(19) United States
(12) Patent Application Publication
(10) Pub. No.: US 2023/0187617 A1
(43) Pub. Date: Jun. 15, 2023

(54) Gradient-Morph LiCoO2 Single Crystals with Stabilized Energy-Density above 3400 Wh/L in Full-Cells

(71) Applicants: Ju LI, Weston, MA (US); Zhi ZHU, Malden, MA (US); Yimeng HUANG, Waltham, MA (US); Massachusetts Institute of Technology, Cambridge, MA (US)

(72) Inventors: Ju LI, Weston, MA (US); Zhi Zhu, Malden, MA (US); Yimeng Huang, Waltham, MA (US)

(73) Assignee: Massachusetts Institute of Technology, Cambridge, MA (US)

(21) Appl. No.: 17/996,069

(22) PCT Filed: Apr. 13, 2021
(86) PCT No.: PCT/US2021/027036

§ 371 Date: Oct. 12, 2022

Related U.S. Application Data
(60) Provisional application No. 63/009,372, filed on Apr. 13, 2020.

(51) Int. Cl. H01M 4/36; H01M 4/485; H01M 4/525; H01M 4/505

(52) U.S. Cl. CPC H01M 4/366; H01M 4/485; H01M 4/525; H01M 4/505

(57) ABSTRACT

A cathode particle has a core and an outer layer. The core includes a lithium (Li) transition metal (M) oxide. The outer layer is disposed conformally around and substantially encloses the core. The core facilitates oxygen anion redox activity and M cation redox activity. The outer layer substantially prevents oxygen anion redox and oxygen loss in the outer layer. The outer layer of the cathode particle may have a first crystal structure. The outer layer's first crystal structure may be at least one of a layered crystal structure or a spinel crystal structure. The core of the cathode particle may have a second crystal structure that is a layered crystal structure. The core may have a single-crystalline structure. The outer layer may be LiMn_{0.75}Ni_{0.25}O₂ or LiMn_{0.5}Ni_{0.5}O₄.

### CROSS-REFERENCE TO RELATED PATENT APPLICATION(S)

The present application claims priority to U.S. provisional application No. 63/009,372, filed on Apr. 13, 2020, entitled “GRADIENT-MORPH LiCoO2 SINGLE CRYSTALS WITH STABILIZED ENERGY-DENSITY ABOVE 3400 Wh/L IN FULL-CELLS,” which is incorporated herein by reference in its entirety.

### BACKGROUND

Lithium cobalt oxide (LiₓCoO₂ or LCO) is a cathode material for lithium-ion batteries (LIBs) with a high specific energy. LCO has a layered crystal structure that accommodates lithium-ion intercalation during battery discharge. LCO cathodes still take a dominant position in the current lithium-ion battery (LIB) market for consumer electronics. LCO cathodes have good rate performance, scalability, and a high compressed density of above 4.1 g/cc. However, in order to maintain cycling stability, LCO cathodes are conventionally operated within a limited voltage range (<4.35 V) and specific capacity (<165 mAh/g). This specific capacity is far below LCO's theoretical capacity of 274 mAh/g.

The cycling stability of LCO at higher charging voltages (>4.5 V) has been investigated. Some reports have found that bulk phase transformations (including O3→H1-3→O1) occurred at voltages above 4.5 V vs. Li/Li⁺, causing rapid degradation of LCO. Other reports have found that the highly delithiated Li₁₋ₓCoO₂ (x>0.5) at voltages above 4.5 V vs. Li/Li⁺ aggravated interfacial side reactions between LCO and the electrolyte.

### SUMMARY

Embodiments of the invention include a cathode particle including a core and an outer layer. The core includes a lithium (Li) transition metal (M) oxide. The outer layer is disposed conformally around and substantially encloses the core. The core facilitates oxygen anion redox activity and M cation redox activity. The outer layer substantially prevents oxygen anion redox and oxygen loss in the outer layer.

The outer layer of the cathode particle may have a first crystal structure. The outer layer's first crystal structure may be at least one of a layered crystal structure or a spinel crystal structure. The core of the cathode particle may have a second crystal structure that is a layered crystal structure. The core may have a single-crystalline structure.

The cathode particle's core and outer layer may be a solid solution. The cathode particle may have a gradient morphology with an increasing concentration of the outer layer with increasing radial distance from the center of the cathode particle. The oxygen in the cathode particle may be in a substantially solid phase. The cathode particle's core may include a first oxygen sublattice. The cathode particle's outer layer may include a second oxygen sublattice that is substantially the same as the first oxygen sublattice (e.g., the two sublattices having a mismatch of about ˜5% to about 5%).

In one implementation, the cathode particle's outer layer may include Li, manganese (Mn), nickel (Ni), and oxygen (O). The ratio of Mn to Ni may be about 3:1. The ratio of Li to MN may be about 0.5:2. The outer layer may include of at least one of LiMn_{0.75}Ni_{0.25}O₂ or LiMn_{1.5}Ni_{0.5}O₄. In another implementation, the outer layer includes Li, aluminum (Al), Mn, and O. The ratio of Mn to Al may be about 1:1. The outer layer may include XLiMn_{1.5}Ni_{0.5}O₄·(1−X) LiMnAlO₄, where X is about 0.3 to about 0.7.

Another embodiment of the present technology includes a method of changing a state of charge of a particle comprising a lithium (Li) transition metal (M) oxide. The method includes (A) applying at least one of a charge voltage or a positive current to the particle, and (B) applying at least one of a discharge voltage or a negative current to the particle. During step (A), oxygen in the core of the particle is oxidized, and oxygen proximate to and at the surface of the particle is substantially prevented from being oxidized. During step (B), oxygen in the core of the particle is reduced, and oxygen proximate to and at the surface of the particle is substantially prevented from being reduced. During steps (A) and (B), oxygen loss from the particle is substantially prevented.

Another embodiment of the present technology includes a cathode particle including a core and an outer layer. The core includes lithium (Li) cobalt (Co) oxide. The outer layer conformally coats the core. The outer layer includes a lithium (Li) transition metal (M) oxide where M comprises manganese (Mn) and nickel (Ni).

Another embodiment of the present technology includes a method of electrochemically cycling a cathode particle. The method includes applying at least one of a charge voltage or a positive current to the cathode particle, and applying at least one of a discharge voltage or a negative current to the cathode particle. The cathode particle includes a core and an outer layer. The core includes lithium (Li) cobalt (Co) oxide. The outer layer conformally coats the core and includes a lithium (Li) transition metal (M) oxide where M comprises manganese (Mn) and nickel (Ni). Another embodiment of the present technology includes a method of forming a cathode particle. The method includes synthesizing a LiCoO₂ core; coating the LiCoO₂ core with an outer layer having a layered structure; and applying a cycling voltage to the cathode particle with a magnitude greater than or equal to about 4V vs. Li/Li⁺ to transform the outer layer layered structure to an outer layer having a spinel structure. The outer layer may include a lithium (Li) transition metal (M) oxide. M may include manganese (Mn) and at least one of nickel (Ni) and aluminum (Al).

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

### BRIEF DESCRIPTION OF DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally similar and/or structurally similar elements).

FIG. 1A is a schematic of a gradient-morph cathode particle.

FIG. 1B is a schematic showing the creation of a gradient-morph X₍ᵣ₎LiCoO₂·(1−X₍ᵣ₎LiMn_{0.75}Ni_{0.25}O₂ single-crystal with an abnormal grain growth using high temperature annealing.

FIG. 1C shows the lattice structure in the coherent core-shell gradient-morph X₍ᵣ₎LiCoO₂·(1−X₍ᵣ₎LiMn_{0.75}Ni_{0.25}O₂ single-crystal particle in a lithiated state (left) and a fully-delithiated state (right).

FIG. 1D shows the electronic structures in LiCoO₂ and Co-free LMO (M=Mn, Ni etc.).

FIG. 2A shows the X-ray diffraction pattern of the P-LCO and G-LCO particles.

FIG. 2B shows SEM images of P-LCO (left) and G-LCO (right) particles.

FIG. 2C shows STEM images of the G-LCO particle after FIB preparation and EDX mapping of Co, Mn, and Ni elements.

FIG. 2D shows an SEM image with EDX mapping of the G-LCO particles.

FIG. 2E shows STEM-HAADF images of the crystal lattices within the G-LCO particle from the LiMn_{0.75}Ni_{0.25}O₂ shell (left) and the LCO bulk (right).

FIG. 2F shows EELS patterns showing the O K-edge, Mn L-edge, and Co L-edge from the surface (bottom) to the bulk (top) from the EELS line-scans across a G-LCO particle.

FIG. 2G shows the composition of elements in the G-LCO particle at different depths calculated from EELS line-scan data.

FIG. 2H shows quantitative analysis of the TEY sXAS Mn L₃ edge for G-LCO particle with linear fitting of the standard references inserted.

FIG. 3A shows the charge/discharge profiles of P-LCO and G-LCO cathode within 3.0 V-4.6 V in coin-cell half-cells under a constant current of 50 mA/g.

FIG. 3B shows the cycling capacity, energy density and Coulombic inefficiency (CI) of P-LCO and G-LCO cathodes within 3.0 V-4.6 V in coin-cell half-cells.

FIG. 3C shows the cycling capacity of P-LCO and G-LCO cathodes at different rates within 3.0 V-4.6 V in coin-cell half-cells.

FIG. 3D shows the cycling performance of the capacity and energy density of P-LCO and G-LCO in pouch full-cells with commercial graphite anodes with a constant charge current of 100 mAh/g to 4.50 V-4.55 V, and then 20 mAh/g again to 4.50 V-4.55 V, and a constant discharge current of 100 mAh/g to 3.0 V.

FIG. 3E shows a comparison of the volumetric energy density of a commercial LCO cathode and G-LCO cathodes.

FIG. 4A shows differential electrochemical mass spectrometry (DEMS) in charging a P-LCO cathode (left) and G-LCO cathode (right) to 4.6 V.

FIG. 4B shows the in situ 2D Co valence mapping (left) and XANES Co K edge (right) in P-LCO particles (top) and G-LCO particles (bottom) at different voltages in the charging process.

FIG. 4C shows XANES Co K-edge near site S at the surface of P-LCO particle (left) and site T at the surface of G-LCO particle (right) (marked in FIG. 4B) after charging to 4.6 V.

FIG. 5A shows a HRTEM image of a G-LCO particle, showing the phase transformation to spinel in the shell, while the core keeps a layered structure in the G-LCO particle.

FIG. 5B shows a STEM-HAADF image of the intersection of the shell and the core, showing the coherency between the spinel shell and the LCO core. The simulated structures of spinel LiMn_{1.5}Ni_{0.5}O₄ (left) and LiCoO₂ (right) are also shown.

FIG. 5C shows the oxygen sublattice matching of LiMn_{1.5}Ni_{0.5}O₄ (111) (lower left) and Co₃O₄ (111) (lower right) against LCO (001). d's are the distances between O atoms in the sublattices.

FIG. 5D is a table of oxygen sublattice misfit strain (δ) and atomic pair distance (δ) of LiMn_{1.5}Ni_{0.5}O₄ and Co₃O₄ against LCO.

FIG. 5E shows the sXAS TEY Mn L₃-edge of G-LCO in the discharged state before cycling and after 2 cycles, where the Mn valence was quantitatively analyzed by linear-fitting from the standard MnO, Mn₂O₃ and MnO₂ references.

FIG. 5F shows the sXAS FY O K-edge spectra of P-LCO (left) and G-LCO (right) at different states of charge in the first cycle.

FIG. 5G shows the charge/discharge profiles of P-LCO (left) and G-LCO (right) in the initial 10 cycles when cycled within 3.0 V-4.7 V in half-cells with 100 mA/g.

FIG. 6A shows an SEM image (left) of the P-LCO electrode after 200 cycles; HRTEM images (middle) of the P-LCO particles after FIB preparation at site A near the particle surface and site B in the particle bulk in the SEM image; and a SAED pattern of the cores in P-LCO particles.

FIG. 6B shows an SEM image (left) of the G-LCO electrode after 200 cycles; HRTEM images (middle) of the G-LCO particles after FIB preparation at site A near the particle surface and site B in the particle bulk in the SEM image; and a SAED pattern of the cores in G-LCO particles.

FIG. 7A shows Li⁺ diffusivity of the full-cells assembled with P-LCO and G-LCO cathodes respectively and commercial graphite anodes in the 3^{rd} cycle and 200^{th} cycle.

FIG. 7B shows EDX mapping of C (top left), F (bottom left), and Co (right) at the graphite anode after 300 cycles in a full-cell with a P-LCO cathode.

FIG. 7C shows EDX mapping of C (top left), F (bottom left), Co (middle) and Mn (right) at the graphite anode after 300 cycles in a full-cell with a G-LCO cathode.

### DETAILED DESCRIPTION

The inventors have realized an opportunity to achieve a higher energy density cathode through the manipulation of the cathode material's bulk and surface degradation initiators during electrochemical cycling. At high voltages, cathode materials may undergo reactions that result in low cycling stability. For example, delithiation at high voltage may involve the oxidation of O²⁻ leading to increased oxygen mobility and escape from the cathode, and causing cathode lattice collapse and reaction with the electrolyte. The oxidation of O²⁻ is an example of hybrid anion- and cation-redox (HACR) reactions that may be involved when charging cathode materials to high capacities.

HACR reactions with O²⁻ oxidization make oxygen ions more mobile and facilitate oxygen migration (OM). OM can be local or global: global OM (GOM) means the oxygen ions can move long-range in the particle including the surface and be released from the particle surface, possibly reacting with the liquid electrolyte, and causing oxygen depletion with particularly pernicious irreversible phase transformations (IPTs). The oxygen loss and electrolyte oxidation are irreversible. Furthermore, these reactions may not be self-limiting (self-passivating), as oxygen loss may produce rampant oxygen vacancies (Vo) in the cathode that “infect” the interior of the cathode, producing flaws and microcracks in the cathode, and further driving GOM and the IPT process propagating deep into the interior of the cathode.

Allowing HACR reactions in the cathode while substantially preventing GOM may facilitate high voltage, high-capacity cycling. Previous attempts to passivate the surface of cathode particles have used foreign coatings. For example, coatings of metal oxides, metal fluorides, and metal phosphates have been previously investigated. While these coatings improved the cycling stability, it was unclear if the coatings fully wet the surface of the cathode particle and prevented GOM because the coatings were structural incoherent with the crystal structure of the cathode particles.

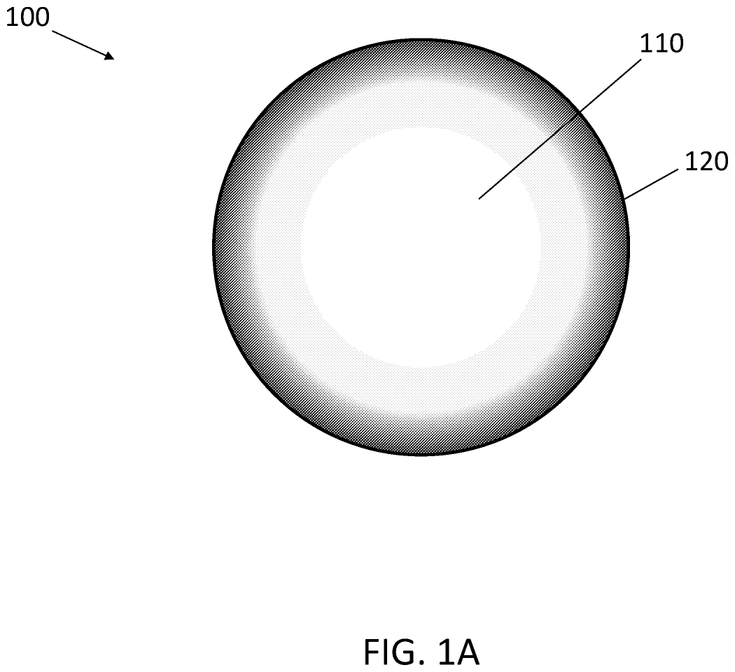

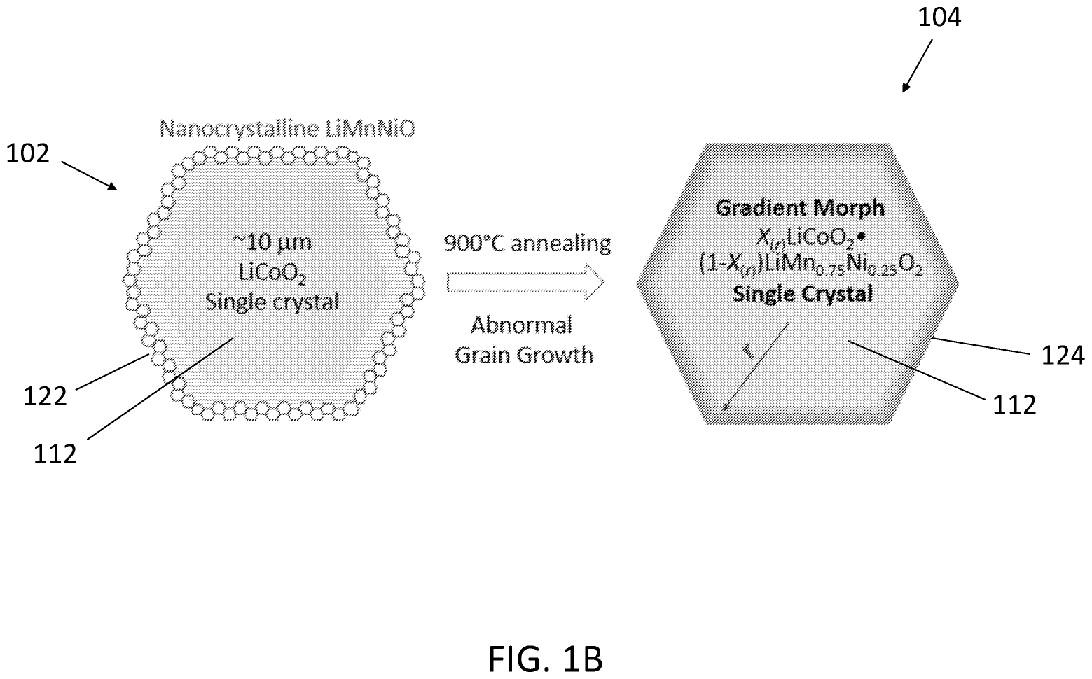

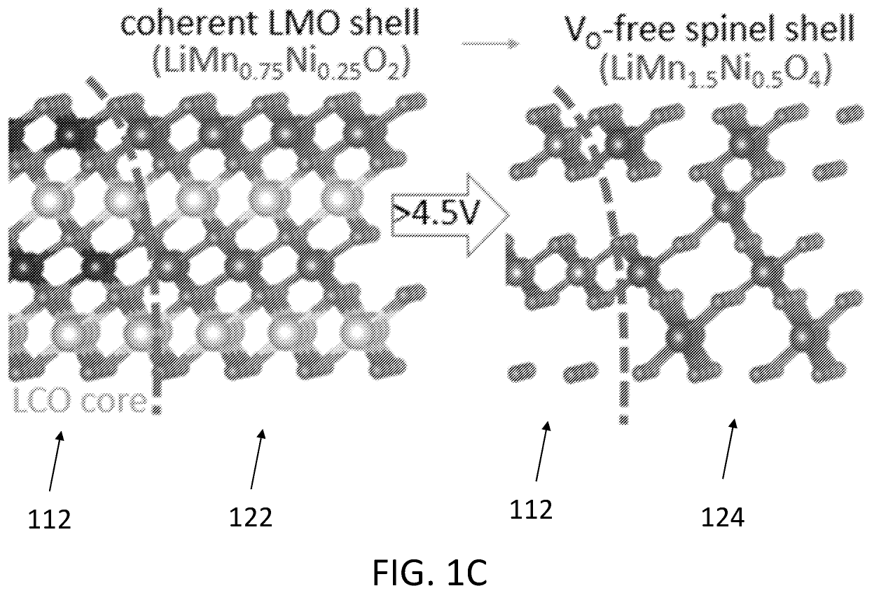

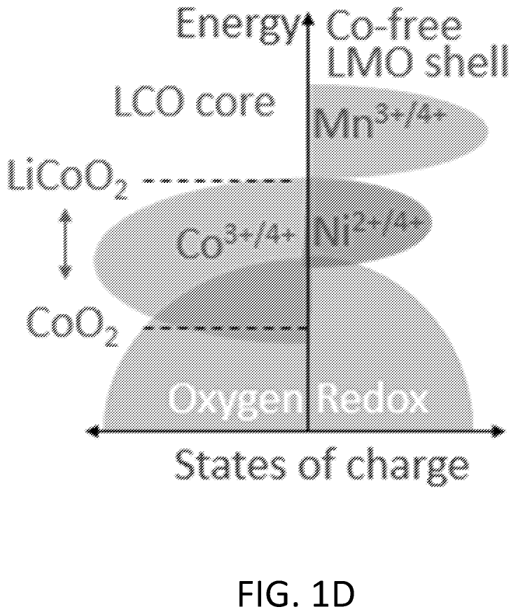

FIG. 1A shows a cathode particle 100 with a lattice-coherent coating 120 around a cathode core 110, where the coating establishes a robust shell around the particle. The coating 120 substantially prevents GOM and IPT in the cathode particles, while maintaining facile Li⁺ and polaron transport in high-voltage cycling. Unlike coatings that are deposited with island growth, the lattice-coherent coating 120 provides an integral shell that fully encloses the cathode lattice. In other words, the coating completely wets the surface of the particle. Coatings deposited with island growth may provide prolific grain boundaries and/or exposed surfaces that may facilitate GOM and stress-corrosion cracking (SCC). The lattice-coherent coating 120 is highly conductive for both Li ions and electrons in the electrochemical environment to promote fast electrochemical kinetics. The lattice-coherent coating 120 does not substantially participate in oxygen anion-redox and substantially excludes oxygen vacancies in cycling to prevent or reduce percolation paths for GOM in the cathode particle.

The lattice-coherent coating 120 is able to fully enclose the core 110 of the cathode particle 100 because of similarities in the crystal lattices of the coating 120 and cathode particle core 110. More specifically, oxygen ions in the lattice-coherent coating 120 share a similar sub-lattice (e.g., having a sublattice mismatch of about −5% to about 5%) with the core 110 of the cathode particles. To facilitate this coherency, the core 110 may have a single crystalline structure.

Lattice-coherent coated cathode materials may be prepared by first coating cathode particles with a lithium metal oxide material that has a similar crystal structure and lattice constant. For example, the coating 120 and core 110 may share a layered crystal structure and/or have similar lattice constants. The similarities in crystal structure between the core 110 and the coating 120 facilitate a conformal coating around the cathode particle 100. The coating 120 and the core 110 form a solid solution with a smooth gradient transition that promotes lattice coherency between the coating 120 and the core 110. The coating 120 may have a gradient morphology (“gradient-morph”) with increasing concentrations of the coating 120 with increasing radial distance from the core 110 of the particle. In an embodiment, the coating 120 material may be transformed in operando during electrochemical cycling to a more stable crystal structure. For example, a coating material that initially has a layered crystal structure may be transformed to a spinel crystal structure during initial electrochemical cycles (e.g., the first 3-5 cycles). In another embodiment, the coating 120 may be transformed to a more electrochemically-stable crystal structure using chemical leaching prior to electrochemical cycling. The lattice-coherent coating does not include metal elements with strong O₂ₚ hybridization, such as cobalt.

Generally, this lattice-coherent gradient-morph single-crystal structure may be established for many cathode materials. As long as the core and the shell are isostructural, they can form a lattice-coherent solid solution during high-temperature calcination. The example presented below describes a single-crystalline LCO particle with a lattice-coherent LiMn_{1.5}Ni_{0.5}O₄ shell. Any element or elements that have the same average valence as Mn_{1.5}Ni_{0.5} in LiMn_{1.5}Ni_{0.5}O₄ and form a spinel crystal structure with Li and O may be used as the shell (coating) material. For example, in one embodiment, the lattice-coherent shell may be LiMnAlO₄. In another embodiment, the lattice-coherent shell may be XLiMn_{1.5}Ni_{0.5}O₄·(1−X) LiMnAlO₄, where X is about 0.3 to about 0.7. In addition to LCO, other single-crystal core materials may be used. For example, large single-crystal nickel-rich NMC particles may be enclosed within a thin coherent Mn-rich lithium manganese oxide (LMO) shell. This material may suppress Ni migration during high-voltage cycling.

Single-Crystalline LCO Particle with a Lattice-Coherent LiMn_{1.5}Ni_{0.5}O₄ Shell

The cycling stability of LiCoO₂ under high voltage (>4.5 V) was plagued by hybrid anion- and cation-redox (HACR) induced problems such as oxygen escape and incoherent phase transformations. With DEMS and in situ nano-XANES mapping at NSLS-II with 21 nm pixel resolution, the inventors demonstrated that oxygen loss triggers an irreversible phase transformation that rapidly propagates inward in the particle. Facilitating HACR in the particle core but stopping global oxygen migration (GOM) may facilitate a reversible and stable high-energy density cathode. The inventors developed ˜10 μm single crystal cathode particles with LiCoO₂ in the core smoothly transitioning to a Co-free LiMn_{0.75}Ni_{0.25}O₂ shell at the particle surface through abnormal grain growth. The shell had a thickness in the range of tens of nanometers (e.g., about 2 nm to about 50 nm). With electrochemical cycling, a coherent LiMn_{1.5}Ni_{0.5}O₄ nanoshell was created in operando with little oxygen loss. The nanoshell completely coated the layered LiCoO₂ core, substantially stopping GOM and thus resulting in enhanced oxygen anion-redox reversibility and phase stability. This cathode material exhibits substantially stabilized cycling when charged to above 4.6 V vs Li/Li⁺. This cathode material demonstrated a stable cyclic volumetric energy density>3400 Wh/L in a pouch full-cell with a commercial graphite anode and very lean electrolyte (3 g/Ah). The pouch full-cell exhibited cyclic retention up to 2906 Wh/L, even after 300 cycles.

FIG. 1B shows an exemplary preparation of a single-crystalline LCO particle 104 with a lattice-coherent LiMn_{1.5}Ni_{0.5}O₄ shell coating 124. The coated particle 104 was prepared by first coating an LCO particle with Mn-rich LiMn_{0.75}Ni_{0.25}O₂ to create particle 102 with an LCO core 112 and a LiMn_{1.5}Ni_{0.5}O₄ shell 122. LiMn_{0.75}Ni_{0.25}O₂ has a layered phase and is not electrochemically stable. Because of its electrochemical instability, Mn-rich LiMn_{0.75}Ni_{0.25}O₂ is rarely implemented as a battery material. LiMn_{1.5}Ni_{0.5}O₄ was coated onto LCO particles as a precursor for the preparation of a lattice-coherent LiMn_{1.5}Ni_{0.5}O₄ coating.

The particles 102 were composed of X₍ᵣ₎LiCoO₂·(1−X₍ᵣ₎)LiMn_{0.75}Ni_{0.25}O₂. The core 112, with X(r_{core})=1, was pure LCO, and X₍ᵣ₎ gradually decreased to 0 (X(r_{surface})=0) from the bulk to the surface 122. That is, the composition in the particle changed from LCO to LiMn_{0.75}Ni_{0.25}O₂ from core 112 to shell 122, but the metal and oxygen ions shared a coherent layered lattice, shown in FIG. 1B. Because of the coherent layered lattice, the core-shell particle 102 promoted a conformal gradient of LiMn_{0.75}Ni_{0.25}O₂ to LiCoO₂ single crystal.

Because of Jahn-Teller distortion, as will be described in more detail in a later section, LiMn_{0.75}Ni_{0.25}O₂ 122 transformed to LiMn_{1.5}Ni_{0.5}O₄ spinel 124 in the initial electrochemical cycles, as shown in FIG. 1C. The LiMn_{1.5}Ni_{0.5}O₄ spinel shell 124 that transformed in operando from the lattice-coherent LiMn_{0.75}Ni_{0.25}O₂ shell 122 during cycling at room-temperature keeps lattice-coherency with the LCO core 112. Crucially, unlike LiₓCoO₂→Co₃O₄, the LiMn_{0.75}Ni_{0.25}O₂→Li_{y}Mn_{1.5}Ni_{0.5}O₄ transformation involves Li loss, but does not involve oxygen loss, and therefore the reaction does not inject oxygen vacancies (Vo) into the cathode particle 104 that may promote GOM. The LiMn_{1.5}Ni_{0.5}O₄ shell 124 is very stable up to 5 volts (V), facilitating high-voltage cycling of the cathode material. To the inventors' knowledge, no one has previously achieved a conformal and coherent LiMn_{1.5}Ni_{0.5}O₄ shell 124 around the LCO core 112 lattice, as described herein.

Though the LiMn_{1.5}Ni_{0.5}O₄ shell 124 has a cubic-spinel structure and the LCO core 112 has a layered structure, the two compositions share a similar oxygen-sublattice coherence. This coherence facilitates a gradient morphology of the single crystal cathode particle 104 (G-LCO). Unlike uncoated LCO, G-LCO does not exhibit GOM-mediated degradation during electrochemical cycling.

In uncoated, pristine LCO (P-LCO), because of the strong Co_{3d}—O₂ₚ hybridization, deep delithiation from LCO may extract electrons from both Co and O ions. FIG. 1D shows the energy resonances of the elements in the shell material. Cobalt (Co) and oxygen (O) have much stronger covalency than Ni_{3d}—O₂ₚ or Mn_{3d}—O₂ₚ. When L₁₋ₓCoO₂ is delithiated beyond x=0.5, further delithiation may facilitate the oxidation of O²⁻ (O²⁻→O^{α-}, α<2). Therefore, HACR reactions may be involved when charging LCO to above ˜150 mAh/g. Although utilizing the last one-half of LCO's theoretical capacity (from 150 mAh/g to 274 mAh/g) in the high-voltage range may initially improve performance, the involvement of oxygen anion-redox and the associated oxygen mobility and escape, causes lattice collapse in the cathode particles and reaction with the lean electrolyte, leading to very poor cycling stability.

Oxygen mobility during cycling of P-LCO may lead to IPTs. A particularly pernicious IPT in P-LCO is CoO₂→Co₃O₄. On average, O²⁻ ions are only minorly oxidized in Li₁₋ₓCoO₂ when charged to 4.5 V (x=0.7). However, the particle surface typically delithiates more to drive the Li ions diffusing from bulk to surface in charging, so that GOM and IPT can be more easily switched on from the particle surface. The oxygen loss (CoO₂→Co₃O₄) with cobalt reduction (Co⁴⁺→Co^{2.7+}) and electrolyte oxidation are irreversible.

In contrast, G-LCO demonstrated unique performance in high-voltage cycling. With ˜10 μm single crystals, 4.1 g/cc compressed density and high electronic conductivity, the cathode cycled to ˜190 mAh/g, ˜230 mAh/g and ˜270 mAh/g when charged to 4.5 V, 4.6 V and 4.7 V vs Li/Li⁺. While the spinel shell contributed little capacity, it was very stable and may keep the crystals dense during cycling. Though the O²⁻ ions in the LCO bulk participated in HACR and may have migrated when charged to above 4.5 V, the O²⁻ ions were completely enclosed and stabilized by the lattice-coherent shell. GOM and IPT were thus efficiently prevented, which “tamed” the oxygen ions in the LCO core to be highly-reversible anion-redox reactions (“solid oxygen” concept like the Li-Sulfur chemistry) during high-voltage cycling. In this work, the inventors showed that the cycling stability of G-LCO was highly applicable for consumer electronics applications even when cycled to 4.7 V.

Substantially different from simple surface passivation, the coherent LiMn_{1.5}Ni_{0.5}O₄ shell conducted Li⁺ and polarons exceptionally well, promoting high interfacial kinetics in cycling. By keeping the valence of Mn at +4 in cycling, the LiMn_{1.5}Ni_{0.5}O₄ shell prevented both Co and Mn dissolution, thereby further stabilizing the cycling of practical full-cells with graphite anodes. Furthermore, the new particles demonstrated better compatibility with a commercial carbonate electrolyte at high voltage. G-LCO demonstrated ultra-stable high-voltage cycling in a pouch full-cell with a commercial graphite anode and very lean electrolyte (3 g/Ah).

Preparation of LiMn_{0.75}Ni_{0.25}O₂→LiCoO₂ Gradient Single Crystals

As the valence of Mn in the LiMn_{0.75}Ni_{0.25}O₂ formula is below +4, such layered-lattice is not easy to prepare in air. However, the inventors demonstrated that a thin coherent LiMn_{0.75}Ni_{0.25}O₂ shell can be created at the surface of a LCO particle, which acted as a seed for the rapid grain coarsening that consumed the original Li/Mn/Ni oxides nanograins, with a composition-gradient region between the LCO core and the LiMn_{0.75}Ni_{0.25}O₂ shell. A lattice-coherent LiMn_{0.75}Ni_{0.25}O₂ shell was created on the pristine LCO (P-LCO) particle with a wet-coating process followed by high-temperature annealing and grain growth. Though the deposited Li/Mn/Ni layer had an opportunity to self-nucleate to other crystal structures (e.g., spinel) and grow into islands at the LCO particle surface, this process was substantially prevented by limiting the thickness of the Li/Mn/Ni precursor layer. Because the thickness of the Li/Mn/Ni precursor layer was sufficiently small compared to the size of the LCO particle, the LCO crystal coarsened away nanocrystalline grains in the Li/Mn/Ni precursor layer during the calcination process due to grain coarsening. The Li/Mn/Ni precursor layer thickness was about 2 nm to about 50 nm on a ˜10 μm LCO particle. Because LiMn_{0.75}Ni_{0.25}O₂ is isostructural with LCO, the two components can mutually diffuse and form a lattice-coherent solid solution when annealed at high temperature. Therefore, the new particle may maintain a single-crystalline morphology. The core of the particle is pure LCO, and the shell has a Mn/Ni/Co gradient concentration.

In an exemplary method of preparing the G-LCO particles, first, the pristine LiCoO₂ single crystal particles were synthesized using a solid-reaction method. Then the coating was added to the particles. Firstly, Co₃O₄ (≥99%, Sigma-Aldrich) and Li₂CO₃ (ACS Reagent, ≥99%, Sigma-Aldrich) were sufficiently mixed with a mole ratio of 1:1.5 (with 5% excess of Li₂CO₃), then the mixture was heated at 1000˜1100° C. for 10 hours with a heating and cooling rate of 5° C./min to get the pristine LCO particles (P-LCO). The pristine LCO particles were centrifuged with water to remove the small particles with sizes smaller than 1 micrometer. Then the shell was deposited onto the particles by sonicating the particles in an ethanol solution with LiCOOCH₃ (Reagent Plus®, ≥99%, Sigma-Aldrich), Mn(COOCH₃)₂ (Reagent Plus®, ≥99%, Sigma-Aldrich) and Ni(COOCH₃)₂ (Reagent Plus®, ≥99%, Sigma-Aldrich) dissolved in a mole ratio of 1.05:0.75:0.25. After that, the mixture was dried in a 60-80° C. water bath with stirring. Then, the obtained powder was heated at 900° C. for 8 hours to get the gradient-morph single-crystal product (G-LCO).

Characterization of LiMn_{0.75}Ni_{0.25}O₂→LiCoO₂ Gradient Single Crystals

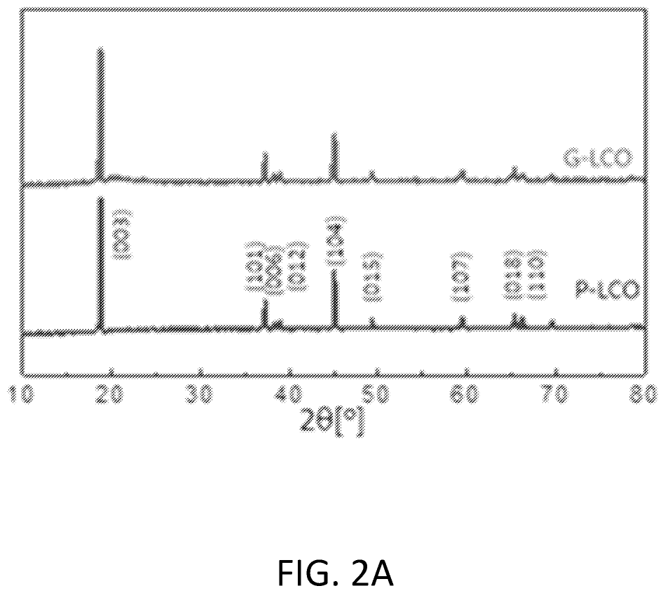

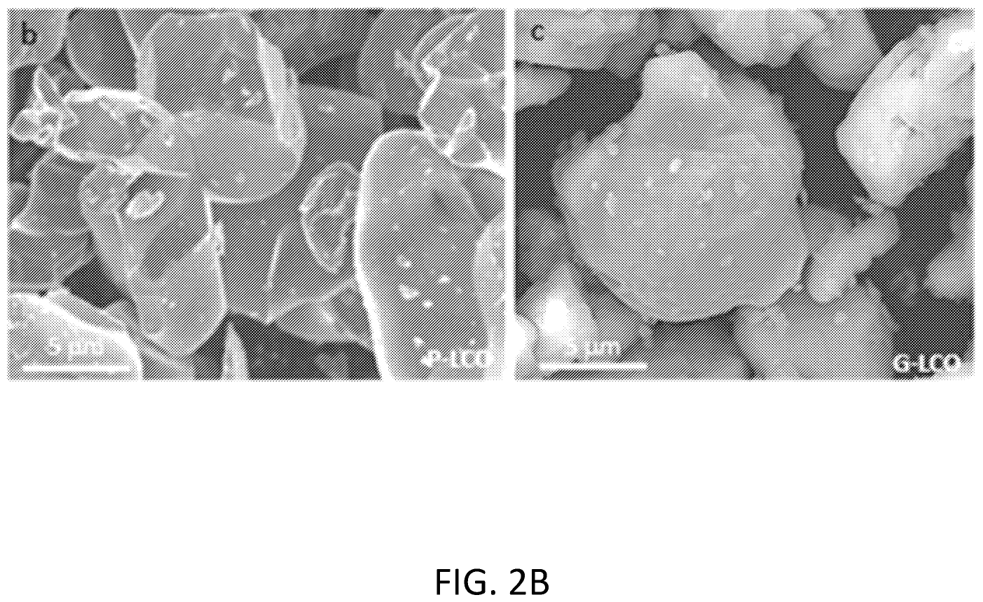

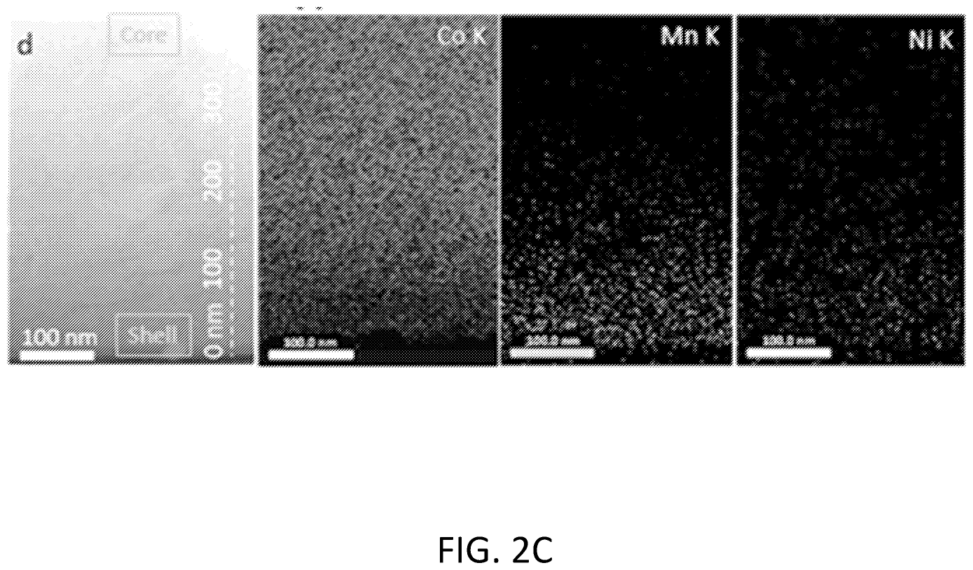

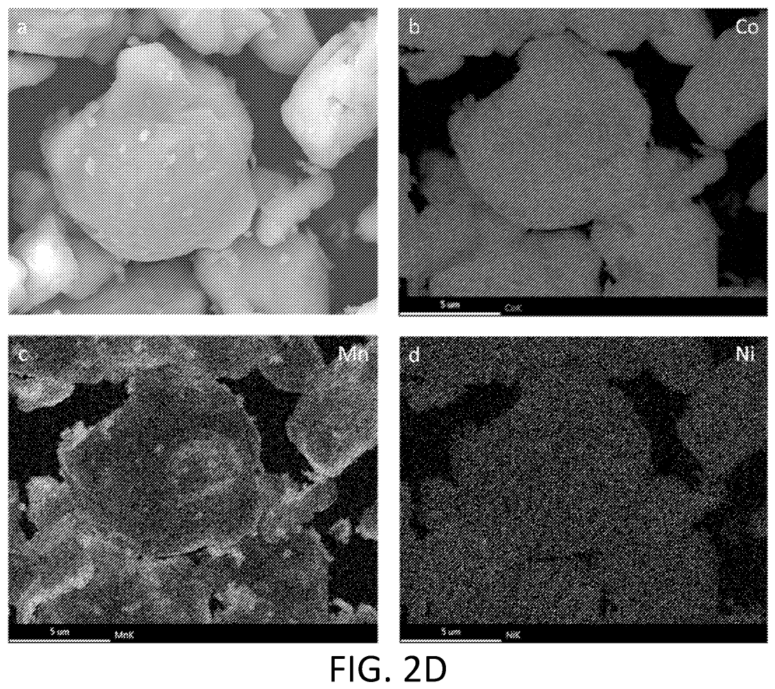

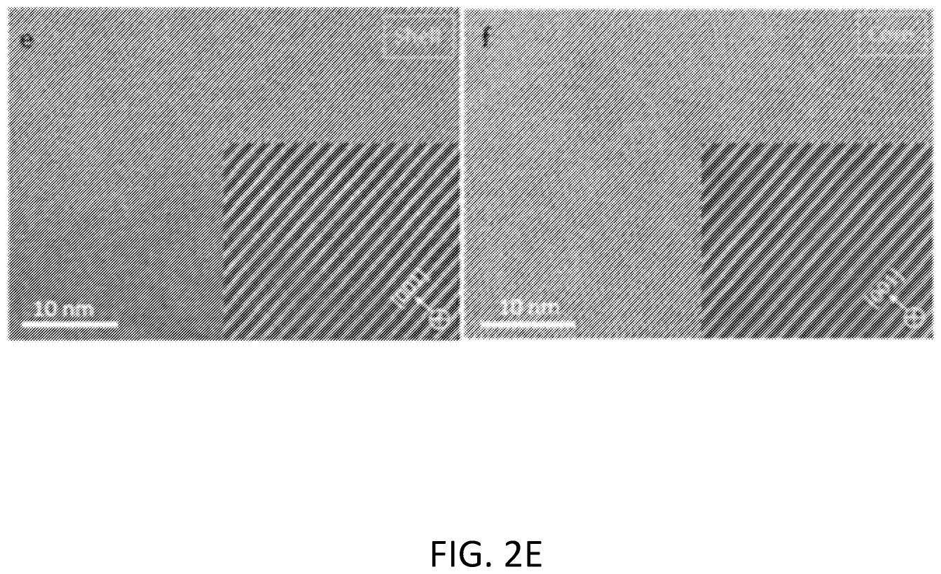

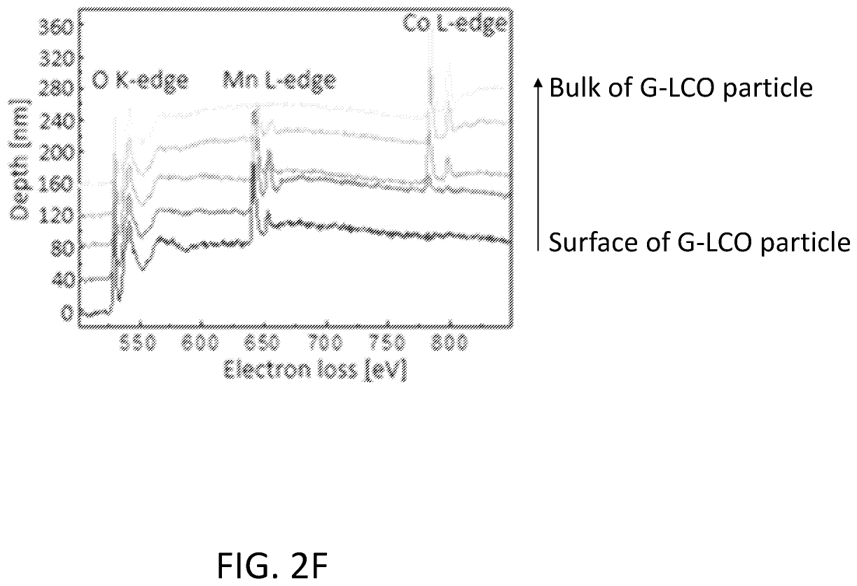

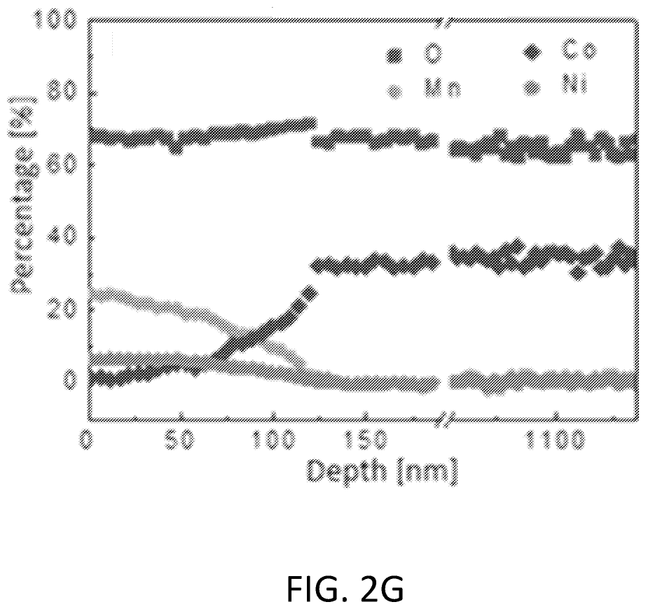

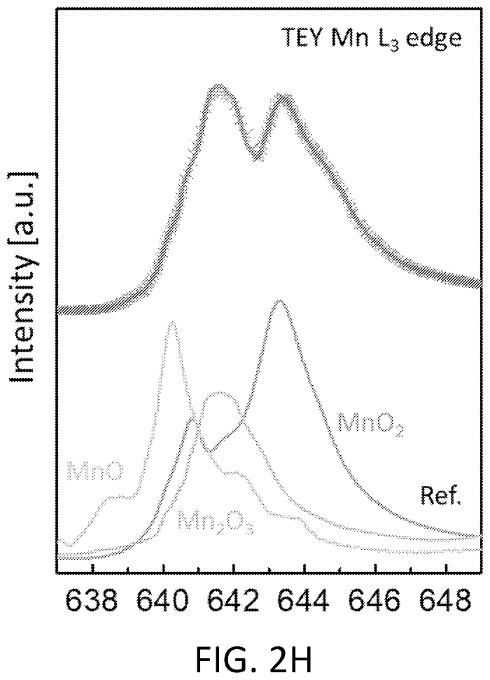

The G-LCO particles were characterized before electrochemical cycling. G-LCO particles were produced with 94 weight percent LCO and 6 weight percent LiMn_{0.75}Ni_{0.25}O₂. The X-ray diffraction (XRD) pattern in FIG. 2A indicated that G-LCO particles still comprised of a single phase, as there was not any other peak observed than the R3m phase. FIG. 2B shows scanning electron microscopy (SEM) images of P-LCO (left) and G-LCO particles (right). P-LCO particles had well-crystallized morphology and smooth surfaces with an average particle size of 5 μm-15 μm in diameter. The G-LCO particles became round and were completely enclosed after creating the coherent shell. The STEM image of the particle cross-section (after FIB) in FIG. 2C (left) indicated that there was no phase boundary in G-LCO. The HRTEM and STEM-HAADF images in FIG. 2E further indicated single-crystallinity of the particle, as the (003) lattice appeared to be well arranged from the deep core of the particle to the outermost surface. The EDS mapping of G-LCO particles in FIGS. 2C and 2D showed that the metal (M) element in the core was Co only and the Co content gradually decreased towards the surface of the particles. Within ˜150 nm from the surface edge of the particles, Mn and Ni were concentrated. The particles did not have a sharp distinction between the Mn/Ni and Co distributions, indicating that the two compositions of LiMn_{0.75}Ni_{0.25}O₂ and LCO formed a solid solution with a smooth gradient transition that promoted lattice-coherency between the LiMn_{0.75}Ni_{0.25}O₂ shell and the LCO core. In FIGS. 2F and 2G the Mn/Co/Ni distribution in G-LCO were quantified with EELS line-scans from the shell to core of the G-LCO particle. These results showed that Co had an elemental concentration of about 33% (consistent with LCO) in the core of the particle. The Co concentration gradually decreased towards the surface of the particle starting at about 150 nm from the surface edge. In the region about 10 nm from the outermost surface of the particle, the Co concentration was 0% (Co-free). In this region, Mn and Ni gradually increased in concentration from 0% to about 25% and about 8%, respectively, (consistent with LiMn_{0.75}Ni_{0.25}O₂). Through the entire particle, O remained at a constant concentration of about 67%.

The above measurements indicated the successful preparation of the gradient X₍ᵣ₎LiCoO₂·(1−X₍ᵣ₎LiMn_{0.75}Ni_{0.25}O₂ single crystals, with X(r_{core})=1 and X(r_{surface})=0. Additionally, FIG. 2H shows the sXAS analysis, indicating the Mn valence was quantified as +3.4 at the surface, quite close to the theoretical value in LiMn_{0.75}^{(+3.33)}Ni_{0.25}⁽⁺²⁾O₂, which further indicated the composition of LiMn_{0.75}Ni_{0.25}O₂ at the G-LCO surface. Generally, the composition profile of G-LCO may be further improved by adjusting the ratio of Li/Mn/Ni, M elements, and annealing temperatures to change electrochemical performance.

### Stabilized High Cyclic Energy-Density Up to 3400 Wh/L in Coin Cell Half-Cells and Pouch Full-Cells

The cathode electrodes were prepared with industrial standard loadings, comprising of 96 wt. % active sample (G-LCO or P-LCO), 2 wt. % carbon black and 2 wt. % PVDF, with about 17 mg/cm² mass loading on an Al foil. The P-LCO and G-LCO cathodes were first cycled in half-cells between 3.0 V and 4.6 V.

R2032 coin cells were fabricated with the above cathode, Li metal anode, a Celgard 2400 polymeric separator and a commercial electrolyte solution of 1 M LiPF₆ dissolved in a mixture of EC and DEC with a volume ratio of 1:1, and 2 wt. % vinylene carbonate additive. Pouch full-cells were fabricated with the above cathodes, commercial graphite anodes (double-side coated), Celgard 2400 polymer separators, and the commercial electrolyte solution. The amount of electrolyte added to the pouch cell was about 3 g/Ah. A LAND CT2001A 8-channel automatic battery test system (Wuhan Lanhe Electronics) was used for charging/discharging of the cells. An electrochemical workstation (Gamry Instr, Reference 3000) was used for the potentiostatic intermittent titration technique (PITT) with constant potential for 200 seconds followed by 1800 seconds relaxation with a voltage-step of 40 mV from 3.8 V to 4.6 V. The electrochemical tests were carried out at room temperature.

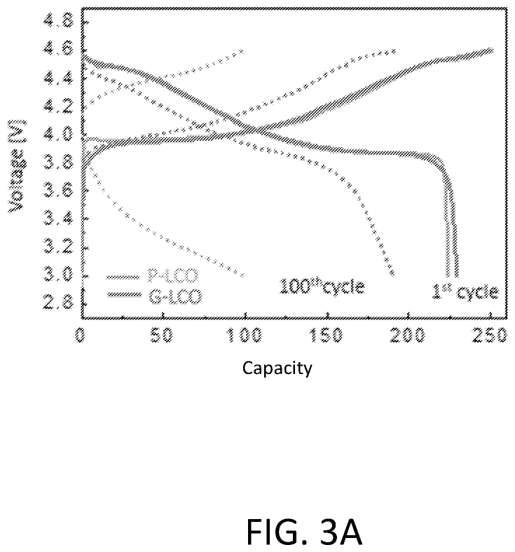

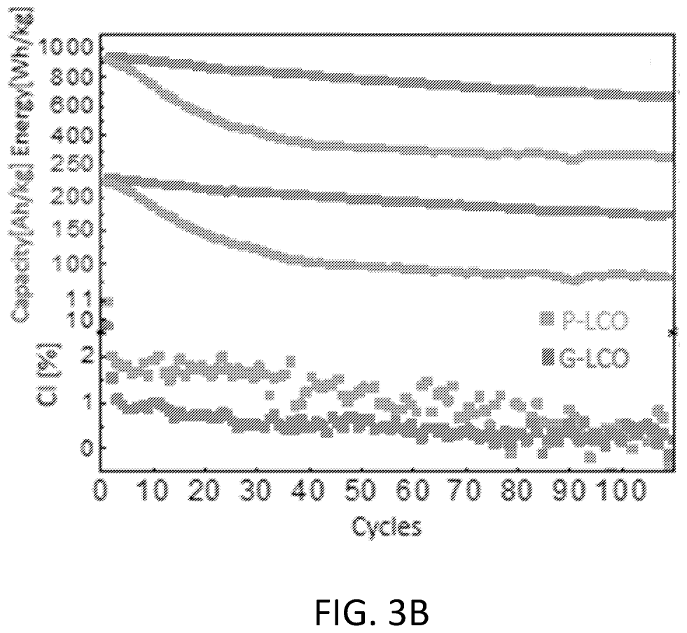

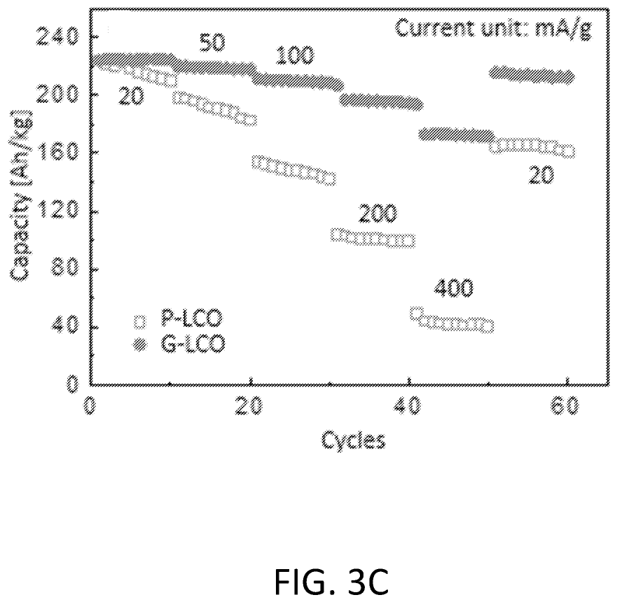

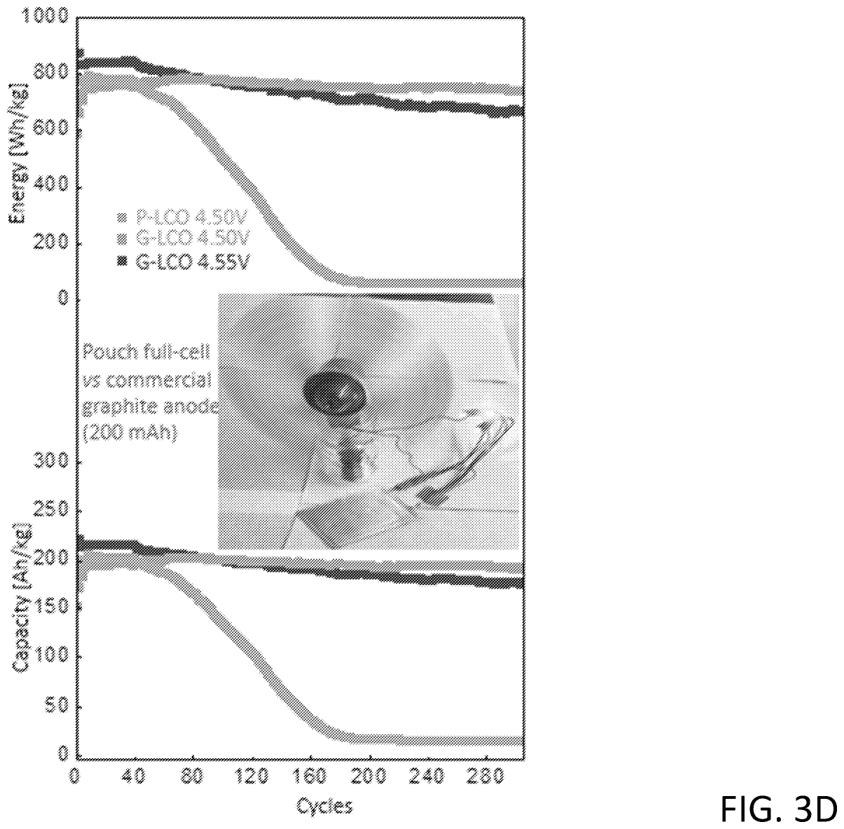

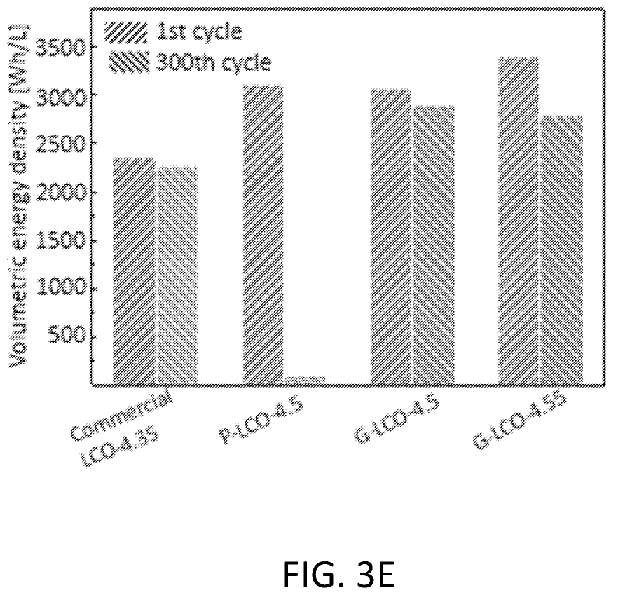

FIG. 3A shows charge/discharge profiles of P-LCO and G-LCO cathodes within a 3.0 V-4.6 V window in coin cell half-cells under a constant current of 50 mA/g. P-LCO and G-LCO cathodes had similar capacity in the 1^{st} electrochemical cycle: The P-LCO cathode was charged to 252.1 mAh/g, and discharged to 224.5 mAh/g. In comparison, the G-LCO cathode was charged to 251.2 mAh/g, and discharge to 226.9 mAh/g. FIG. 3A shows that the charge/discharge profile of the P-LCO cathode significantly faded after 100 cycles, while the charge/discharge profile of the G-LCO cathode maintained a high capacity after 100 cycles.

FIG. 3B shows the cycling performance of P-LCO and G-LCO cathodes within 3.0 V-4.6 V in coin-cell half-cells. The capacity of the P-LCO cathode decayed rapidly in the initial 30 cycles. After 40 cycles, only 45% of the initial capacity and 34% of the initial energy-density of the P-LCO cathode were retained. In comparison, the G-LCO cathode retained more than 80% of its initial capacity and energy density after 100 cycles.

The Coulombic inefficiency (CI) (CI≡1−Coulombic efficiency (CE)) in half-cells was compared for each cathode, indicating the capacity loss in each cycle. As shown in FIG. 3B, the G-LCO cathode had a lower CI than the P-LCO cathode, indicating the G-LCO cathode demonstrated a suppressed capacity loss in each discharge cycle. The suppressed CI of the G-LCO cathode not only indicated a stable thermodynamic retention but could also indicate maintained kinetics of the G-LCO cathode during each charge and discharge. The higher CI of the P-LCO cathode reflected significant kinetic retardation in each cycle, where the growth of Co₃O₄ during charging added an additional impedance for the followed discharge.

The difference in cyclic capacity between P-LCO and G-LCO may be larger at higher rates. FIG. 3C shows the cycling capacity of P-LCO and G-LCO cathodes at different rates within the 3.0 V-4.6 V voltage window in coin-cell half-cells. The G-LCO cathode had a similar capacity to the P-LCO cathode in the initial cycles, cycled at 20 mA/g. The capacity retention of the P-LCO cathode decreased significantly at higher rates. In comparison, the G-LCO cathode's capacity retention decreased little. At 400 mA/g after 40 cycles, the G-LCO cathode still discharged 175 mAh/g, a value three-times higher than that of the P-LCO cathode (41 mAh/g). When the rate was subsequently reduced to 20 mA/g, the capacity of the G-LCO cathode was 210 mAh/g whereas the capacity of the P-LCO cathode was 163 mAh/g. These results indicate that the kinetic capacity loss of the G-LCO cathode, when increasing the cycling rate from 20 mA/g to 400 mA/g, was only about ¼ of that of the P-LCO cathode after 50 cycles. These results indicate that the impedance of the G-LCO cathode was stabilized in high-voltage cycling.

FIG. 3D shows P-LCO and G-LCO cathodes tested in pouch full-cells with a matched commercial graphite anode. FIG. 3D shows the cycling performance capacity and energy density of the P-LCO and G-LCO cathodes in pouch full-cells with a constant charge current of 100 mAh/g to either 4.50 V or 4.55V, and then 20 mAh/g again to 4.50 V or 4.55V, and a constant discharge current of 100 mAh/g to 3.0 V.

As shown in FIG. 3D, both P-LCO and G-LCO cathode pouch cells discharged to about 205 mAh/g and 780 mWh/g in the initial cycles when cycled within 3.0 V-4.50 V. After the initial cycles, the capacity and energy density of the P-LCO cathode pouch cell suffered rapid decay in the first 60 cycles and significantly faded within 200 cycles. In comparison, the G-LCO cathode pouch cell demonstrated very little capacity and energy density decay during cycling. The G-LCO pouch cell maintained a stable capacity of 191.2 mAh/g and an energy density of 736.3 mWh/g after 300 cycles.

FIG. 3D also shows a G-LCO cathode pouch cell cycled within 3.0 V-4.55 V. In this voltage range, the G-LCO cathode pouch cell discharged to 216 mAh/g and 844 mWh/g in the initial cycles and retained 176.3 mAh/g and 664.7 mWh/g after 300 cycles. The previous highest energy-density of LCO obtained in a pouch full-cell with a graphite anode was also around 800 Wh/kg, reported by Zhang et al., Nat. Energy 4, 594-603, (2019). However, in that study, the cycling retention decayed to below 700 Wh/kg in 70 cycles. The G-LCO cathode pouch cell in this work achieved an energy-density retention of 736.3 Wh/kg after 300 cycles. Additionally, the G-LCO cathode pouch cell used very lean electrolyte (3 g/Ah), consistent with commercial manufacturer standards. The high energy-density retention with lean electrolyte use indicates that the G-LCO cathode has excellent compatibility with carbonate electrolytes at high voltages.

The G-LCO cathode demonstrated significantly improved volumetric energy. The compressed densities of the P-LCO and G-LCO electrodes were measured as 4.1±0.1 g/cm³. This compressed density is consistent with current commercial manufacturers. The volumetric energy density of P-LCO and G-LCO cathodes were compared in FIG. 3E. Volumetric energy densities were calculated from the cycling performance in the pouch full-cells shown in FIG. 3D. Though the initial volumetric energy densities of P-LCO and G-LCO were similar when charged to 4.50 V, both around 3100 Wh/L, the volumetric energy density of P-LCO decayed to almost 0 after 300 cycles. In comparison, G-LCO retained a high volumetric energy density of 2906 Wh/L after 300 cycles. When cycled to 4.55 V, G-LCO achieved 3404 Wh/L and retained 2793 Wh/L after 300 cycles. To the inventors' knowledge, this is the first time that these high volumetric energy densities after 300 cycles have been achieved. The volumetric energy density of the G-LCO cathode pouch cell was about 30% higher than that of a commercial LCO cycled within 3.0 V-4.35 V.

### Prevention of GOM and IPT in Fully Delithiated G-LCO Particles

The rapid degradation of P-LCO in high-voltage cycling was likely caused by GOM and the accumulated IPT. Differential electrochemical mass spectroscopy (DEMS) was used to monitor the O₂ and CO₂ released while charging the P-LCO and G-LCO cathodes to 4.60 V vs Li/Li⁺.

A quantitative differential electrochemical mass spectrometry (DEMS) was used to detect and analyze the gas during the cell testing. Two glued polyether ether ketone (PEEK) capillary tubes were used as gas inlet and outlet. The cell was fabricated in a glove box where O₂ was less than 0.1 ppm. The output tube was connected to a Thermo Scientific mass spectrometer (MS). High-purity Ar gas was used as the carrier gas with a flow rate of 3 mL/min during the cycling process. In the constant current charging process, the current was 50 mA/g, and DEMS spectra were collected every 30 seconds.

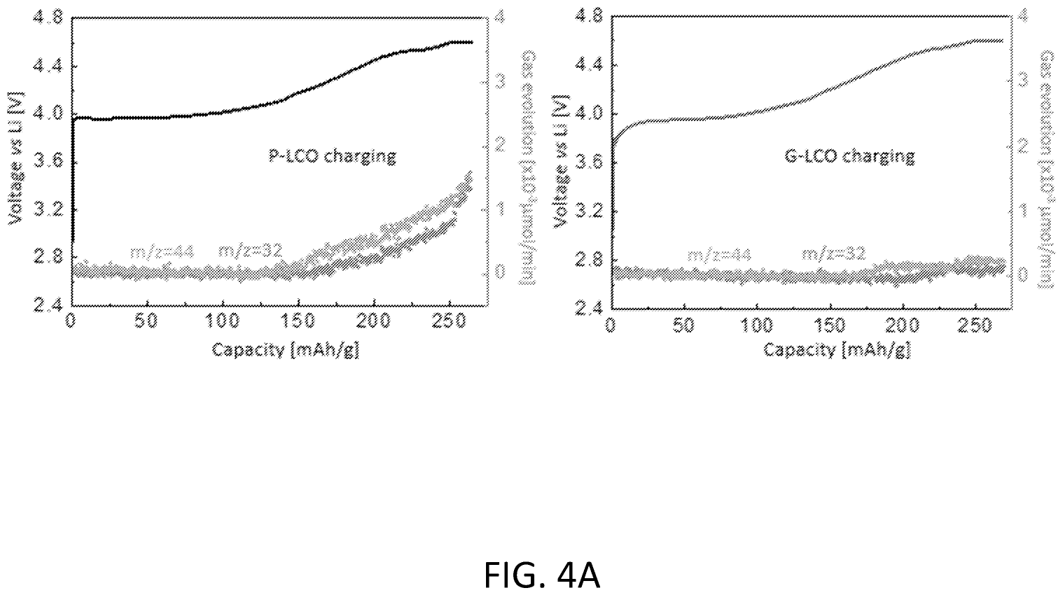

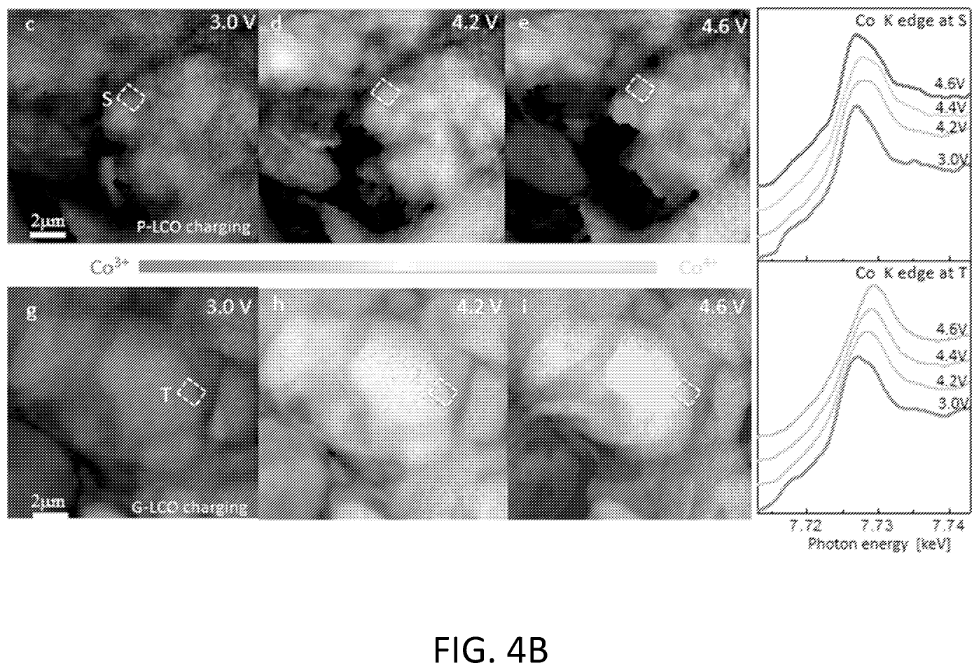

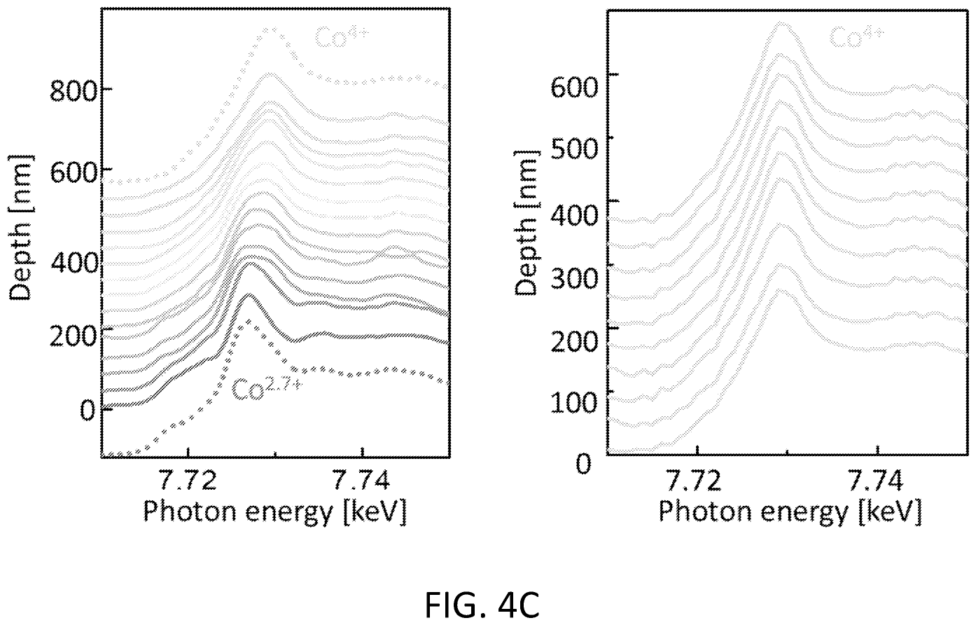

FIG. 4A shows the P-LCO cathode started to release O₂ at 4.3 V (160 mAh/g), and the amount of O₂ released from the P-LCO cathode linearly increased between 4.3 V and 4.60 V. The amount of O₂ released significantly increased when the P-LCO cathode was held at 4.60 V. The accompanying CO₂ release when oxygen was released from the cathode indicated rampant decomposition of the electrolyte. In comparison, GOM was substantially prevented in the G-LCO cathode at high voltage. As shown in FIG. 4A, little O₂ was released from the G-LCO cathode, even when the G-LCO cathode was held at 4.60 V for more than 1 hour. The lack of CO₂ released from the G-LCO cathode also indicated a stabilized interface between the G-LCO particles and the carbonate electrolyte. These results indicate that substantial OM was prevented in the G-LCO cathode, thereby stabilizing the particle surface, and preventing the depletion of the electrolyte during cycling. The occurrence of OM may result in IPT in the P-LCO particle, producing spinel Co₃O₄, where the average Co valence is below +3.

FIG. 4B shows in situ 2D mapping of Co valence states in the cathodes of pouch cells during a charging cycle. FIG. 4B shows Co valence mapping of P-LCO particles (top) and G-LCO particles (bottom) at different voltages during the charging cycle. These images were collected using nano-XANES with synchrotron-based full-field X-ray imaging. The change in color in these images indicates a change in the Co valence. Nano-XANES mapping has a high spatial resolution (˜21 nm) and high temporal resolution.

In situ nano-XANES mapping was performed at FXI beamline (18-ID) at the National Synchrotron Light Source II (NSLS-II), Brookhaven National Laboratory. Pouch-cell configurations with P-LCO and G-LCO as cathodes were used for measurements. Each pouch cell was charged at a constant current of 8 mA and stopped at different voltages (4.2 V, 4,4 V and 4.6 V) while collecting XANES spectra. A volume in the middle of the cell was randomly chosen for imaging. XANES images were taken at different energies across the Co absorption edge (7.588-8.153 keV, 1 eV interval). The effective pixel size of each image was 21 nm. Standard samples (CoO and LiCoO₂) were used to extract the reference absorption spectra for Co²⁺ and Co³⁺ oxidation states.

FIG. 4B (top) shows the in-situ Co valence distribution in P-LCO at different states of charges (SOCs). Mapping showed the particle surface delithiated more than the bulk during charging. At site S at the P-LCO particle surface, Co was oxidized while charging P-LCO from 3.0 V to 4.2 V, indicating normal delithiation of LiCoO₂→Li₁₋ₓCoO₂. However, Co was reduced instead of being further oxidized when it was further charged to 4.6 V.

FIG. 4C shows the XANES Co K edge at the outermost surface of the P-LCO particle (left) and the G-LCO particle (right) at 4.6 V. FIG. 4C shows that the Co ions in the core of the P-LCO particle were oxidized to about a +4 valence state. Co ions near the surface of the P-LCO particle were gradually reduced to a +2.7 valence state. In contrast, all the Co ions in the G-LCO were oxidized to a +4 valence state, including the bulk and the surface of the particle.

Co₃O₄ may have been produced at 4.6 V at site S near the surface of the P-LCO particle, indicating the formation of IPT. GOM and IPT (CoO₂→Co₃O₄) may have initiated at certain locations on the surface of the P-LCO particle at high voltage. The P-LCO particle demonstrated a gradient Co-valence distribution near site S at 4.6 V (FIGS. 4B and 4C). The gradient distribution of Co valence in the P-LCO particle indicated the growth of Co₃O₄ into the bulk of the P-LCO particle. The formation of Co₃O₄ in P-LCO may facilitate significant degradation in the electrochemical performance of P-LCO cathodes at high voltage.

In contrast, the G-LCO particle did not demonstrate any significant GOM or IPT at high voltage. FIG. 4B (bottom) shows Co in the G-LCO particle was continuously oxidized from +3 to about +4 while charging the G-LCO cathode from 3 V to 4.6 V. These nano-XANES results did not show reduction of Co at the surface or the bulk of the G-LCO particle. The formation of Co₃O₄ may have been prevented by preventing GOM in the surface of the G-LCO particle. Consequently, the G-LCO particle maintained fast kinetics during charging, promoting a low CI of less than about 0.5% and an enhanced capacity retention during prolonged high-voltage cycling.

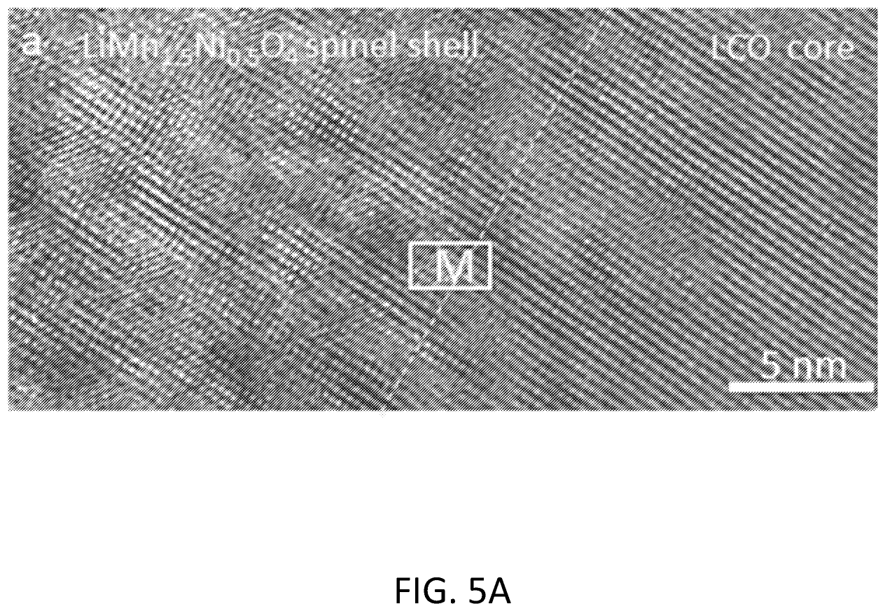

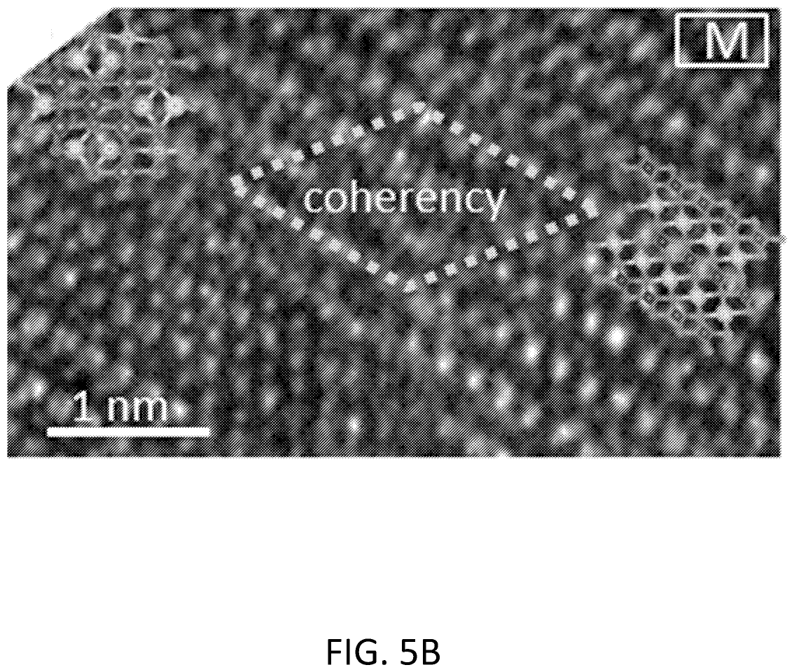

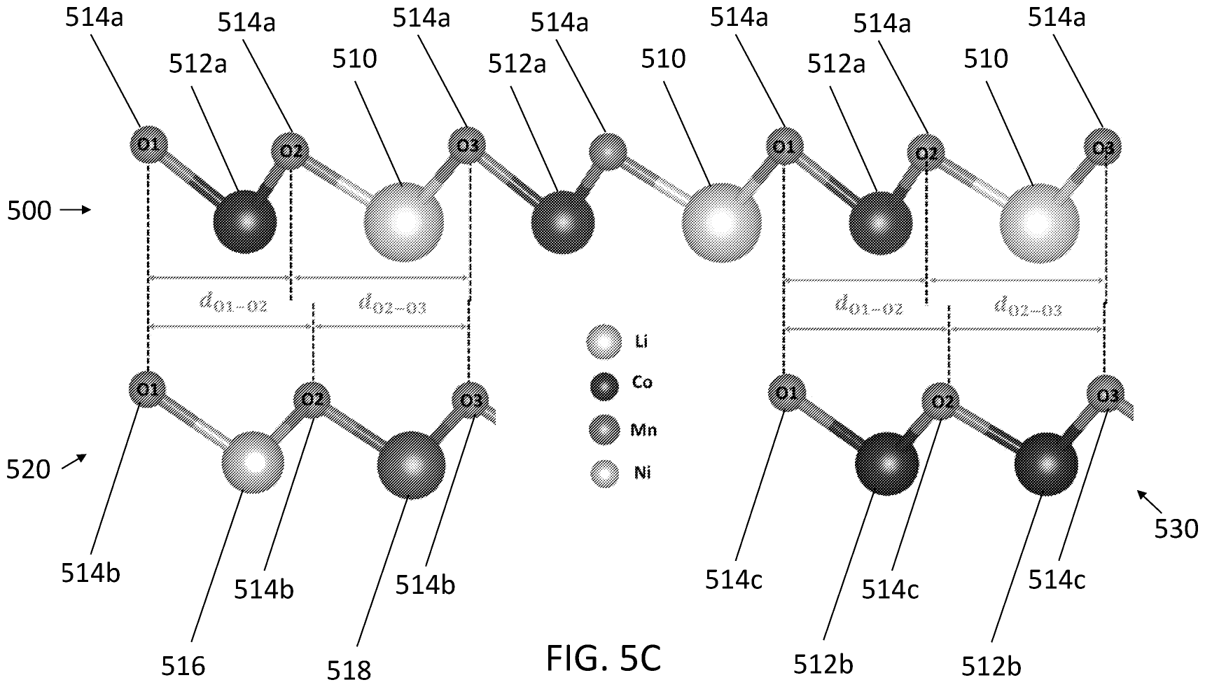

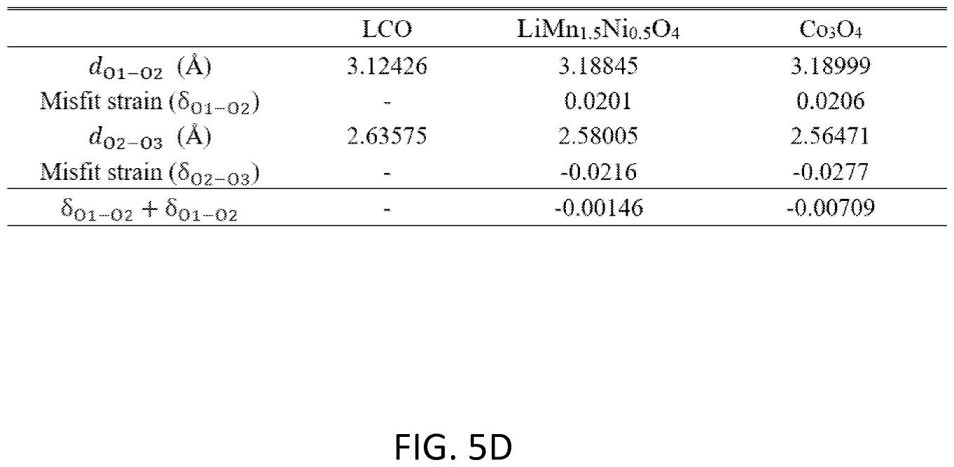

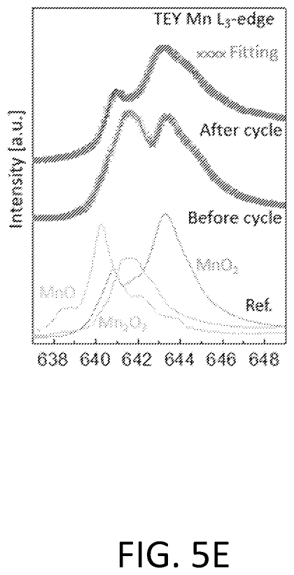

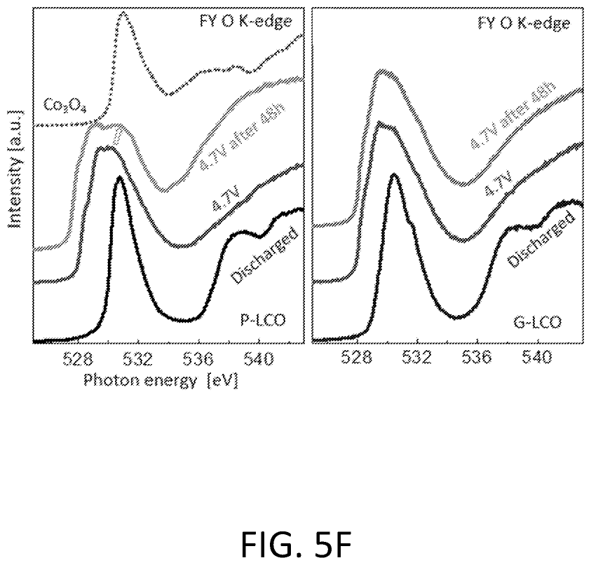

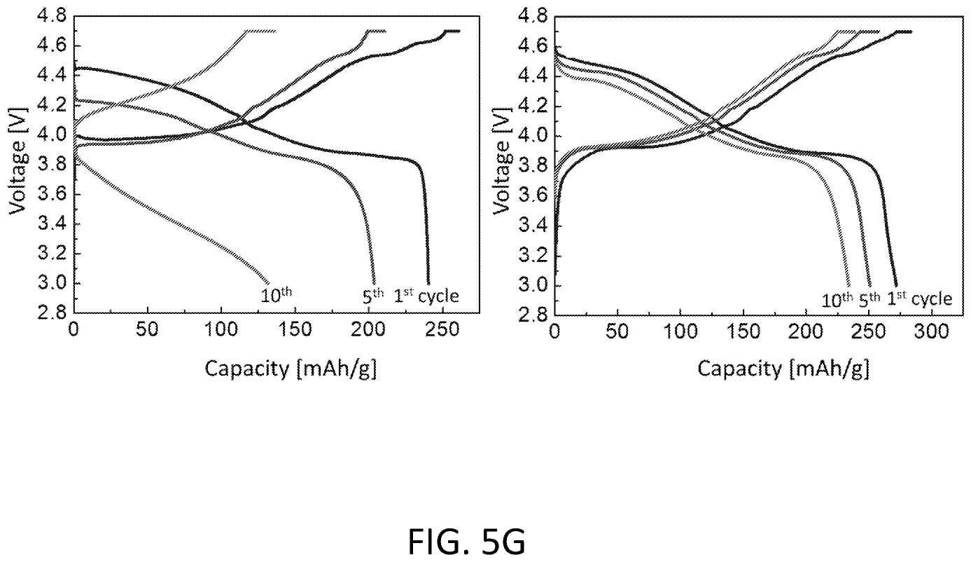

FIG. 5A shows a high-resolution transmission electron microscopy (HRTEM) image of a G-LCO particle after the shell has been converted to a spinel LiMn_{1.5}Ni_{0.5}O₄ with electrochemical cycling. The HRTEM image indicates a layered structure in the core of the particle and a spinel structure in the shell of the particle. The transformation of LiMn_{0.75}Ni_{0.25}O₂→LiMn_{1.5}Ni_{0.5}O₄ in the shell of the particle may be irreversible. Though the LiMn_{1.5}Ni_{0.5}O₄ spinel shell has a different crystal structure than the layered LCO core, the shell kept lattice-coherency with the LCO core.

FIG. 5B shows a STEM-HAADF image of the intersection of the shell and the core, showing the coherency between the operando-created spinel shell and the LCO core. The simulated spinel LiMn_{1.5}Ni_{0.5}O₄ structure (left) and LiCoO₂ structure (right) are inserted in the image. As shown in the image, the shell's phase transformation did not produce phase boundaries or microcracks in the particle. Both the LCO core and LiMn_{1.5}Ni_{0.5}O₄ shell kept a coherent oxygen sublattice.

To reconcile the coherency between LCO and LiMn_{1.5}Ni_{0.5}O₄ found in the HRTEM micrograph in FIG. 5A, the oxygen pair distance and translational invariant between different crystal surfaces was investigated and the oxygen sublattice misfit strain for coherent interfaces was computed. In a dual-phase crystal, if both materials across the boundary have an identical crystal lattice or sublattice with a small discrepancy in their lattice parameters, the interface between them may have high coherency.

FIG. 5C shows the oxygen sublattice structures of LCO (001) 500, LiMn_{1.5}Ni_{0.5}O₄ (111) 520, and Co₃O₄ (111) 530. The LCO lattice includes lithium 510, cobalt 512a, and oxygen 514a. The LiMn_{1.5}Ni_{0.5}O₄ lattice includes manganese 516, nickel 518, and oxygen 514b. The Co₃O₄ lattice includes cobalt 512b and oxygen 514c. FIG. 5C shows oxygen sublattice matching of LiMn_{1.5}Ni_{0.5}O₄ (111) (lower left) and Co₃O₄ (111) (lower right) against LCO (001). d's are the distances between O atoms in the sublattices.

FIG. 5D shows oxygen sublattice misfit strain (δ) and atomic pair distance (δ) of LiMn_{1.5}Ni_{0.5}O₄ and Co₃O₄ against LCO. There are two possible O atom pair distances, namely d_{O1-O2} and d_{O2-O3}, taking place alternatively at the coherent interface for both LCO and LiMn_{1.5}Ni_{0.5}O₄ or Co₃O₄, giving rise to a slight sublattice misfit strain of ˜±2% shown in FIG. 5D. This “Peierls-transition”-like atomic configuration leads to an overall mismatch of only −0.146% for LCO/LiMn_{1.5}Ni_{0.5}O₄ interface and −0.709% for LCO/Co₃O₄ interface, with each repeating unit having exactly one tensile region and one compressive region. This result indicates that the mismatch of LCO/LiMn_{1.5}Ni_{0.5}O₄ is much less than that of the LCO/Co₃O₄ formed in P-LCO during electrochemical cycling. This result indicates a high lattice-coherency between the LCO core and the LiMn_{1.5}Ni_{0.5}O₄ shell created in operando.

The phase transformation and the subsequent high-voltage cycling of the G-LCO cathode did not involve substantial oxygen loss. No O²⁻ oxidation or release from the G-LCO particles was observed. The results indicate that the phase transformation did not introduce oxygen vacancies (Vo) or other flaws into the G-LCO particles.

FIGS. 5E and 5F show sXAS measurements of G-LCO. sXAS measurements were carried out at the IOS beamline (23-ID-2) at the National Synchrotron Light Source II (NSLS-II), Brookhaven National Laboratory. Spectra were acquired in partial electron yield (PEY), total electron yield (TEY) and partial fluorescence yield (PFY) modes. The estimated incident X-ray energy resolution was ˜0.05 eV at the O K-edge. The monochromator absorption features, and beam instabilities were normalized out by dividing the detected PFY and TEY signals by the drain current of a clean gold I0 mesh placed in the incident beam. TEY spectra were recorded from the drain current of the sample and PFY data were acquired using a Vortex EM silicon drift detector. The sXAS spectra for O K-edge were recorded over a wide energy range from 520 to 565 eV covering energies well below and above sample absorptions. The normalization of the O K-edge was performed: 1) I0 normalization: the sample signal was divided by the incident intensity measured from the sample drain current from a freshly coated Au mesh inserted into the beam path before the X-rays can impinge on the sample. 2) A linear, sloping background was removed by fitting a line to the flat low energy region (520-524 eV) of the sXAS spectrum. 3) The spectrum was normalized by setting the flat low energy region to zero and the post-edge to unity (unit edge—jump). The photon energy selected for the post edge was 560 eV, beyond the region of any absorption (peaks).

FIG. 5E shows soft X-ray absorption spectroscopy (sXAS) TEY Mn L₃-edge of G-LCO in a discharged state before cycling and after 2 cycles. The Mn valence was quantitatively analyzed using a linear fit of standard MnO, Mn₂O₃ and MnO₂ references. FIG. 5E shows that the Mn valence at the G-LCO particle surface changed from +3.4 to +4 in the discharged state after about 3 to about 5 cycles. These results were consistent with the LiMn_{0.75}^{(+3.33)}Ni_{0.25}⁽⁺²⁾O₂→LiMn_{1.5}⁽⁺⁴⁾Ni_{0.5}⁽⁺²⁾O₄ transformation and indicated the formation of a substantially Vo-free shell. Therefore, the robust coherent LiMn_{1.5}Ni_{0.5}O₄ shell may stop GOM in the LCO lattice, while allowing HACR and O²⁻ oxidation to occur in the LCO core. Unlike the spinel Co₃O₄ in P-LCO formed during electrochemical cycling, the spinel LiMn_{1.5}Ni_{0.5}O₄ shell does not block Li ion diffusion or electron conductivity. Instead, the LiMn_{1.5}Ni_{0.5}O₄ shell supplies a 3D 8a-16c-8a path to promote fast Li ion diffusion during cycling.

FIG. 5F shows sXAS FY O K-edge spectra of P-LCO (left) and G-LCO (right) at different states of charge in the initial cycle. sXAS was performed to directly investigate HACR by tracking the oxidation states of O at high-voltage. Both P-LCO and G-LCO cathodes were charged to 4.7 V then held for 48 h, and the FY sXAS O K-edges were recorded during this charging process. The FY sXAS O K-edge of both P-LCO and G-LCO shifted leftward when charged to 4.7 V, indicating that O²⁻ ions were oxidized to O^{α-} (α<2) in both P-LCO and G-LCO. After holding the voltage at 4.7 V for 48 h, the FY O K-edge of P-LCO split into two peaks, indicating a partial reduction of O^{α-} ions to O²⁻ due to GOM (e.g., O^{α-}→O²⁻+O₂). In contrast, the O K-edge of G-LCO was nearly unchanged after 48 h at 4.7 V, indicating that the oxidized O^{α-} was significantly stabilized in the G-LCO lattice. The sXAS analysis strongly indicated the prevention of GOM in the G-LCO particles at high voltage, which agreed well with the DEMS and in situ XANES mapping results in FIGS. 4A-4C.

FIG. 5G shows the charge/discharge profiles of a P-LCO cathode (left) and a G-LCO cathode (right) in the initial 10 cycles within a voltage window of 3.0 V-4.7 V in half-cell coin cells with 100 mA/g. While charging, the cathodes were charged to 4.7 V, followed with a constant-voltage charging until the current decreased to 20 mA/g. These profiles indicate that the cycling stability of the G-LCO cathode when cycled to 4.7 V was also much improved compared to that of P-LCO.

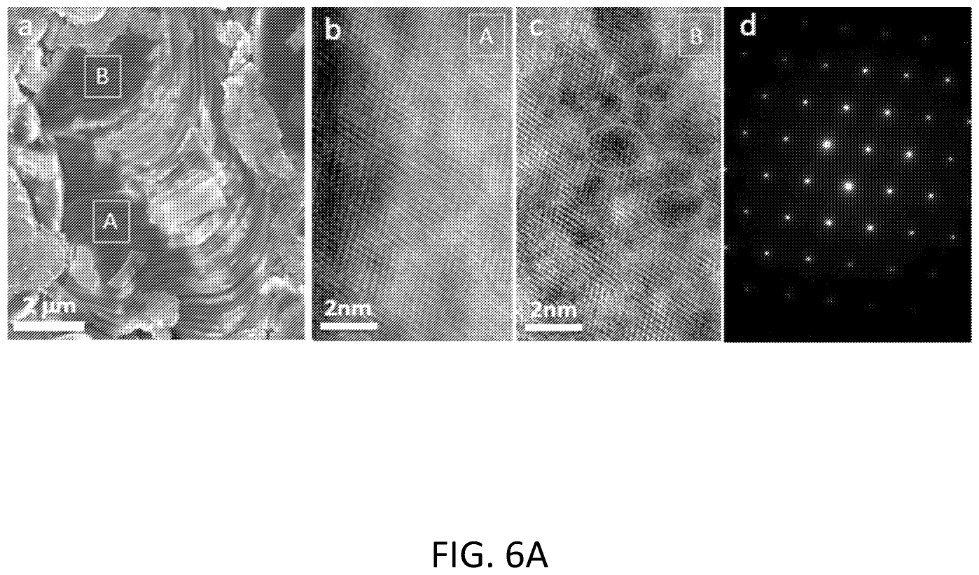

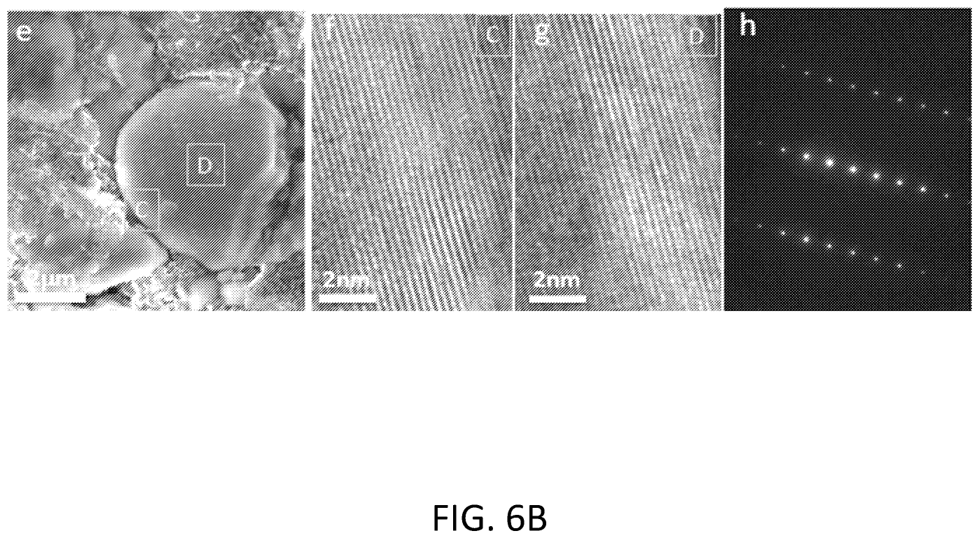

FIGS. 6A and 6B show images of the P-LCO and G-LCO cathodes, respectively, after many high-voltage cycles. Half-cells were cycled between 3.0 V and 4.60 V for 200 cycles. With the operando-created coherent spinel shell, G-LCO maintained a substantially stable structure during high-voltage cycling. In comparison, IPT (Co₃O₄) continuously grew into the bulk of P-LCO.

FIG. 6A shows an SEM image (left) of P-LCO indicating significant cracking and fragmentation of the P-LCO particle surface. The surface layer IPT grew thickly and significantly blocked charge transferring and lithium diffusion. As shown in the HRTEM image of the cross-section of P-LCO after focused ion beam (FIB) preparation in FIG. 6A (middle), the spinel Co₃O₄ was present across most of the particle from the surface (site A in the SEM image) to the center (site B in the SEM image). Circles in the HRTEM images indicate the presence of oxygen voids in the core of the P-LCO particle. These oxygen voids may result from continuous oxygen loss during high-voltage cycling. The selected area electron diffraction (SAED) pattern in FIG. 6A (right) indicated that lots of the layered LCO structure had transformed to spinel Co₃O₄ in the P-LCO particle after 200 cycles.

FIG. 6B shows an SEM image (left) of G-LCO indicating a robust single-crystal morphology after 200 cycles with a voltage range of 3.0 V-4.6 V. The SEM image does not show cracking or fragmentation of the particle surface. The HRTEM images of G-LCO after FIB in FIG. 6B (middle) further indicated the well-maintained layered structure through the LCO core after cycling. The (003) lattice was well arranged in the deep core (site D in the SEM image) and in the shell (site C in the SEM image). The SAED pattern in FIG. 6B (right) additionally indicated that most of the layered structure was maintained in the LCO core.

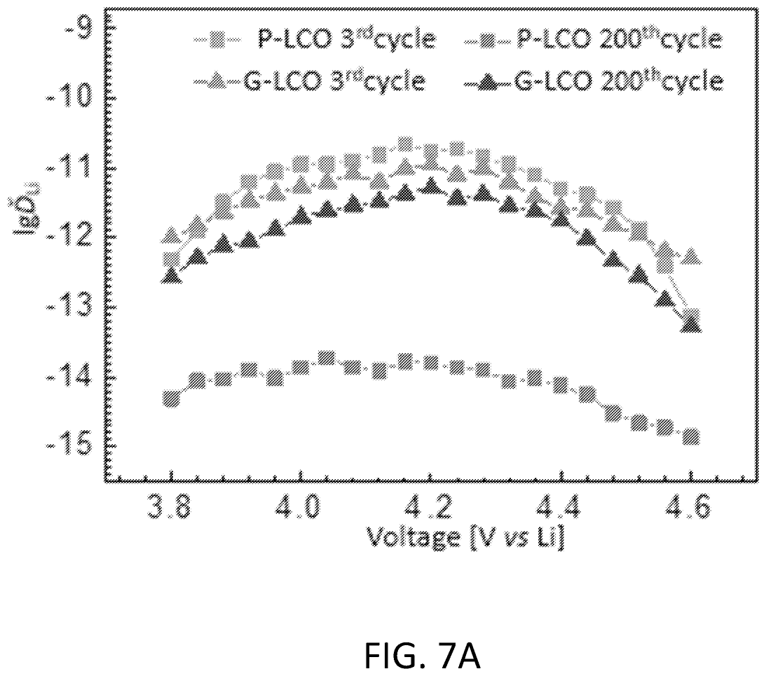

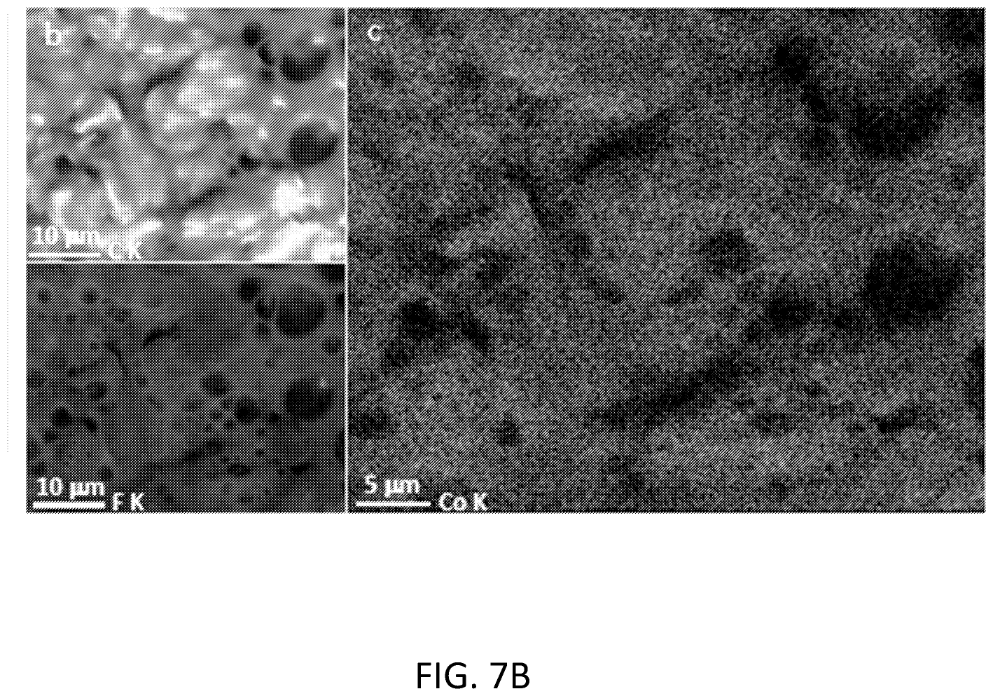

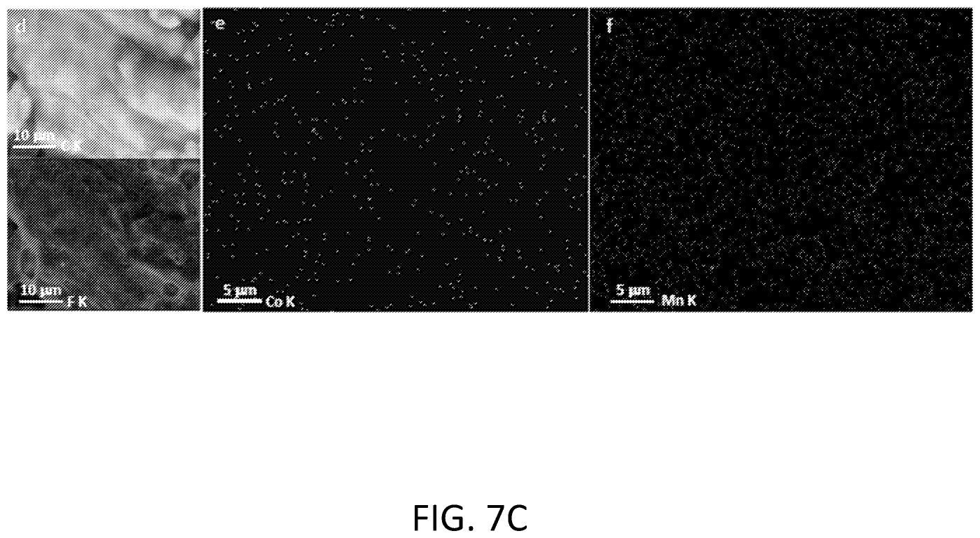

FIG. 7A shows Li⁺ diffusivity in full-cells assembled with P-LCO and G-LCO cathodes respectively and commercial graphite anodes in the 3^{rd} cycle and 200^{th} cycle. Li⁺ diffusivity (Ď_{Li}) can help understand reaction kinetics during cycling. Potentiostatic intermittent titration technique (PITT) was used to quantify Ď_{Li} in the charging process. As shown in FIG. 7a, the Ď_{Li} of P-LCO and G-LCO were similar in the 3^{rd} charging, both between 10⁻¹² cm²/s˜10⁻¹¹ cm²/S; however, Ď_{Li} of P-LCO decreased to around 10⁻¹⁴ cm²/s while that of G-LCO still kept around 10⁻¹² cm²/s after 200 cycles. The Ď_{Li} here refers to the diffusion of Li⁺ ions and polarons in the full-cell, so Ď_{Li} here may indicate the practical electrochemical kinetics of the full-cell. The results indicate that the stabilized structure in G-LCO may maintain better kinetics than P-LCO in high-voltage cycling.

FIGS. 7B and 7C show energy-dispersive X-ray spectroscopy (EDX) mapping of the graphite anodes from the P-LCO full-cell and the G-LCO full-cell, respectively, after cycling. EDX mapping may provide information about the solid electrolyte interface (SEI) formed at the anode. The performance at the graphite anode may affect the kinetics of the cell. A similar amount of F was present at the graphite anode in the P-LCO full-cell and the G-LCO full-cell. The graphite anode in the P-LCO full-cell had a large amount of Co deposited on its surface. In comparison, Co on the graphite anode in the G-LCO full-cell was greatly suppressed. These results indicate that Co dissolution from the cathode and deposition at the anode was suppressed in the G-LCO full-cell. This suppression may facilitate interfacial Li⁺ transfer within the electrodes and cell cycling stability.

Additionally, there was very little Mn detected at the surface of the graphite anode of the G-LCO full-cell after cycling. This result indicates that the Mn in the shell maintained a +4 valence in LiMn_{1.5}⁽⁺⁴⁾Ni_{0.5}⁽⁺²⁾O₄ during high voltage cycling. This result also indicates that the shell in G-LCO did not significantly dissolve in the carbonate electrolyte.

Single-Crystalline LCO Particle with a Lattice-Coherent XLiMn_{1.5}Ni_{0.5}O₄·(1−X)LiMnAlO₄ Shell

In one embodiment, cathode particles have a lattice-coherent shell that includes LiMnAlO₄. For example, the lattice-coherent shell may be XLiMn_{1.5}Ni_{0.5}O₄·(1−X) LiMnAlO₄, where X is about 0.3 to about 0.7. The core of the material may be LCO.

In an exemplary method of preparing G-LCO particles with a XLiMn_{1.5}Ni_{0.5}O₄·(1−X)LiMnAlO₄ shell, first, the pristine LCO single crystal particles were synthesized using a solid-reaction method. Then the coating was added to the particles. The LCO particles were centrifuged with water to remove small particles with diameters less than 1 micrometer. Then the LCO particles were sonicated in an ethanol solution with LiCOOCH₃, Mn(COOCH₃)₂, Ni(COOCH₃)₂, and Al(NO₃)₃ dissolved with a mole ratio consistent with XLiMn_{0.75}Ni_{0.25}O₂·(1−X)LiMn_{0.5}Al_{0.5}O₂, with Li in a 5% excess. After that, the mixture was dried in a 60-80° C. water bath with stirring. The obtained powder was heated at 900° C. for 8 hours to get the gradient-morph single-crystal product (G-LCO).

### CONCLUSION

All parameters, dimensions, materials, and configurations described herein are meant to be exemplary and the actual parameters, dimensions, materials, and/or configurations will depend upon the specific application or applications for which the inventive teachings is/are used. It is to be understood that the foregoing embodiments are presented primarily by way of example and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein.

In addition, any combination of two or more such features, systems, articles, materials, kits, and/or methods, if such features, systems, articles, materials, kits, and/or methods are not mutually inconsistent, is included within the inventive scope of the present disclosure. Other substitutions, modifications, changes, and omissions may be made in the design, operating conditions and arrangement of respective elements of the exemplary implementations without departing from the scope of the present disclosure. The use of a numerical range does not preclude equivalents that fall outside the range that fulfill the same function, in the same way, to produce the same result.

Also, various inventive concepts may be embodied as one or more methods, of which at least one example has been provided. The acts performed as part of the method may in some instances be ordered in different ways. Accordingly, in some inventive implementations, respective acts of a given method may be performed in an order different than specifically illustrated, which may include performing some acts simultaneously (even if such acts are shown as sequential acts in illustrative embodiments).

All publications, patent applications, patents, and other references mentioned herein are incorporated by reference in their entirety.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A cathode particle comprising:
a core comprising a lithium (Li) transition metal (M) oxide, the core substantially facilitating oxygen anion redox activity and M cation redox activity; and
an outer layer disposed conformally around and substantially enclosing the core, the outer layer substantially preventing oxygen anion redox in the outer layer and oxygen loss in the outer layer.

2. The cathode particle of claim 1, wherein:
the outer layer has a first crystal structure that is at least one of a layered crystal structure or a spinel crystal structure; and
the core has a second crystal structure that is a layered crystal structure.

3. The cathode particle of claim 1, wherein the core has a single-crystalline structure.

4. The cathode particle of claim 1, wherein:
the core and the outer layer are a solid solution; and
the cathode particle has a gradient morphology with an increasing concentration of the outer layer with increasing radial distance from a center of the cathode particle.

5. The cathode particle of claim 1, wherein the oxygen in the cathode particle is in a substantially solid phase.

6. The cathode particle of claim 1, wherein:
the core comprises a first oxygen sublattice; and
the outer layer comprises a second oxygen sublattice that has a sublattice mismatch with the first oxygen sublattice of about ˜5% to about 5%.

7. The cathode particle of claim 1, wherein:
the outer layer comprises Li, manganese (Mn), nickel (Ni), and oxygen (O);
the ratio of Mn to Ni is about 3 to 1; and
the ratio of Li to Mn is between about 0.5 and about 2.

8. The cathode particle of claim 1, wherein the outer layer is comprised of at least one of LiMn_{0.75}Ni_{0.25}O₂ or LiMn_{1.5}Ni_{0.5}O₄.

9. The cathode particle of claim 1, wherein:
the outer layer comprises Li, aluminum (Al), manganese (Mn), and oxygen (O); and
the ratio of Mn to Al is about 1:1.

10. The cathode particle of claim 1, wherein:
the outer layer is comprised of XLiMn_{1.5}Ni_{0.5}O₄·(1−X) LiMnAlO₄; and
X is about 0.3 to about 0.7.

11. A method of changing a state of charge of a particle comprising a lithium (Li) transition metal (M) oxide, the method comprising:
(A) applying at least one of a charge voltage or a positive current to the particle; and
(B) applying at least one of a discharge voltage or a negative current to the particle;
wherein:
during step (A), oxygen in the core of the particle is oxidized, and oxygen proximate to and at the surface of the particle is substantially prevented from being oxidized;
during step (B), oxygen in the core of the particle is reduced, and oxygen proximate to and at the surface of the particle is substantially prevented from being reduced; and
during steps (A) and (B), oxygen loss from the particle is substantially prevented.

12. A cathode particle comprising:
a core comprising lithium (Li) cobalt (Co) oxide; and
an outer layer, conformally coating the core, comprising a lithium (Li) transition metal (M) oxide where M comprises manganese (Mn) and nickel (Ni).

13. The cathode particle of claim 12, wherein:
the outer layer has a first crystal structure that is at least one of a layered crystal structure or a spinel crystal structure; and
the core has a second crystal structure that is a layered crystal structure.

14. The cathode particle of claim 12, wherein:
the core is configured to undergo anionic redox reactions of oxygen (O) and cationic redox reactions of M; and
the outer layer is configured to prevent oxidation and reduction of O when the particle is cycled at a sufficiently large voltage or current.

15. The cathode particle of claim 12, wherein:
the core comprises a first oxygen sublattice; and
the surface comprises a second oxygen sublattice that is the same as the first oxygen sublattice.

16. The cathode particle of claim 12, wherein the Li transition metal oxide of the outer layer is at least one of LiMn_{0.75}Ni_{0.25}O₂ or LiMn_{1.5}Ni_{0.5}O₄.

17. The cathode particle of claim 12, wherein:
the outer layer additionally comprises aluminum (Al); and
the ratio of Mn to Al is about 1:1.

18. The cathode particle of claim 12, wherein:
the outer layer is comprised of XLiMn_{1.5}Ni_{0.5}O₄·(1−X) LiMnAlO₄; and
X is about 0.3 to about 0.7.

19. The cathode particle of claim 12, further comprising:
a gradient region, disposed between the outer layer and the core, comprising the lithium cobalt oxide of the core and the lithium transition metal oxide of the outer layer in the form X₍ᵣ₎LiCoO₂·(1−X₍ᵣ₎LiMn_{0.75}Ni_{0.25}O₂ where X₍ᵣ₎ ranges between 0 and 1 and varies as a function of a position, r, along a radial axis of the particle.

20. A method of electrochemically cycling a cathode particle, comprising:
applying at least one of a charge voltage or a positive current to the cathode particle; and
applying at least one of a discharge voltage or a negative current to the cathode particle;
wherein:
the cathode particle comprises:
a core comprising lithium (Li) cobalt (Co) oxide; and
an outer layer, conformally coating the core, comprising a lithium (Li) transition metal (M) oxide where M comprises manganese (Mn) and nickel (Ni).

21. A method of forming a cathode particle, the method comprising:
synthesizing a LiCoO₂ core;
coating the LiCoO₂ core with an outer layer having a layered structure; and
applying a cycling voltage to the cathode particle with a magnitude greater than or equal to about 4V vs. Li/Li⁺ to cause the layered structure to become a spinel structure.

22. The method of claim 21, wherein:
the outer layer comprises a lithium (Li) transition metal (M) oxide; and
M comprises manganese (Mn) and at least one of nickel (Ni) and aluminum (Al).
